(19) United States
(12) Patent Application Publication
(10) Pub. No.: US 2026/0017426 A1
(43) Pub. Date: Jan. 15, 2026

(54) ADAPTIVE SIMULATION PLANNING AND RISK MANAGEMENT SYSTEM USING REAL-TIME AI ANALYSIS

(71) Applicant: The Oracle Partnership Ltd, Hampshire (GB)

(72) Inventors: Peter Kingsley, Hampshire (GB); Simon Tilford, Hampshire (GB)

(21) Appl. No.: 19/087,264

(22) Filed: Mar. 21, 2025

Related U.S. Application Data
(60) Provisional application No. 63/670,001, filed on Jul. 11, 2024.

(30) Foreign Application Priority Data
Mar. 22, 2024 (GB) 2404175.8

(51) Int. Cl. G06F 30/20

(52) U.S. Cl. CPC G06F 30/20

(57) ABSTRACT

Systems and methods are disclosed for dynamic simulation planning and monitoring of emerging narratives. The system ingests real-time real-world event feeds from multiple sources, generates simulations based on selected parameters, and encodes predicted outcomes of new emerging narratives in a dynamic simulation matrix. Machine-learning model-based search for breakthroughs continuously updates the simulation matrix to reflect changing conditions. The system also includes features such as generation of alerts and new simulations in response to breakthroughs or new information, monitoring key indicators, and generation of directed acyclic graphs (DAGs) to visualize interdependencies between macro-variables. Users can interact with the dynamic simulation matrix, selecting specific variables or interventions to explore further. The system enables proactive decision-making by anticipating and preparing for emerging trends and narratives.

### CROSS-REFERENCE TO RELATED APPLICATIONS

This application is a continuation and claims the priority benefit of U.S. provisional patent application 63/670,001 filed on Jul. 11, 2024, and U.K. Patent application GB2404175.8 filed on Mar. 22, 2024. The disclosures of the aforementioned applications are incorporated herein by reference.

### FIELD OF DISCLOSURE

The present disclosure is generally related to uncertainty, risk, governance strategic policy management, and innovation, particularly pertaining to simulation and early warning of future events within complex adaptive systems.

### BACKGROUND

Predicting and preparing for complex events such as natural disasters, economic crises, and global conflicts has always been a challenge for governments, institutions, and individuals. Traditional methods of forecasting rely heavily on historical data and statistical models, which are limited in their ability to anticipate truly novel or unexpected events or scenario outcomes or simulation outcomes. The increasing complexity and interconnectedness of modern systems have created a perfect storm of uncertainty, making it difficult to accurately assess or predict the emergence of cascading events and consequences of human actions, natural events, or the interplay between them.

Current systems for identifying emerging threats and opportunities are limited. Policymakers, corporate leadership, and intelligence teams rely on historical evidence and instinct, which hinders their ability to anticipate new hazards or opportunities. Human analysis is restricted by its inability to understand complex system non-linear dynamics, latent interdependencies, and feedback loops that create uncertainty. Existing models are based on historical data and are often static, linear, and backward-looking. They fail to account for human behavior, weak leadership, political division, and radical innovation.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1 illustrates a risk management system.

FIG. 2 illustrates an example diagram for generating a simulated outcome and displaying results in a dynamic simulation matrix dashboard.

FIG. 3 illustrates an example dynamic simulation matrix dashboard.

FIG. 4 illustrates an example expanded view of one of the interactive cards.

FIG. 5 illustrates a control module.

FIG. 6 illustrates a parameter identification module.

FIG. 7 illustrates a simulation model module.

FIG. 8 illustrates a data collection module.

FIG. 9 illustrates a risk assessment module.

FIG. 10 illustrates a story module.

FIG. 11 illustrates an action module.

FIG. 12 illustrates an example method for generating a dynamic simulation matrix.

FIG. 13 illustrates a block diagram of an exemplary computing system.

FIG. 14 illustrates an example neural network architecture.

### DETAILED DESCRIPTION

Current systems for identifying emerging threats and opportunities are limited. Policymakers, corporate leadership, and intelligence teams rely on historical evidence and instinct, which hinders their ability to anticipate novel hazards or opportunities. Human analysis is restricted by its inability to understand complex system non-linear dynamics, latent interdependencies, and feedback loops that create uncertainty. Existing models are based on historical data and are often static, linear, and backward-looking. They fail to account for human behavior, weak leadership, political division, and radical innovation.

There is a need for a systematic, foresight-based and strategic intelligence methodology that can make emerging risk and transformational innovation transparent. Current models are inherently weak and incomplete due to the lack of understanding and transparency about inter-systemic risk and the secret worlds of invention.

The present technology addresses this problem by providing simulations that are not restricted to considering historical or current information flows about events. It utilizes narrative models, algorithms, and searches for related data to identify emerging threats and opportunities. This system can efficiently consider complex, intertwined simulations, including predicted outcomes characterized by competing or contested or emerging future outcomes over time.

The present technology collects additional data and performs a risk assessment for identified low-probability events based on the collected data. It arranges this data into narratives to improve communication of identified hazards and their risk to decision-makers. This allows policymakers and strategists to select desirable outcomes, monitor current status and momentum towards those outcomes, and adjust policy accordingly. By using computers to process immense amounts of data and perform simulations, this system can unlock the ability to consider complex simulations that humans may be incapable of managing. It efficiently simulates, detects and identifies anomaly patterns, their emergence, and momentum toward an outcome, providing improved prediction accuracy and early warning and the ability to identify low-probability or “black swan” events.

This present technology detects and tracks in real-time or near real-time emerging systemic and inter-systemic risks and breakthrough events or discoveries. It is capable of dynamic early detection of novel events never seen before, emerging risk events, developments, tipping points, cascades, and impacts of complex relationships and interdependent variables over time by simulating future events and tracking for signs of their emergence over time. It leverages state-of-the-art natural language processing and targeted emotion and sentiment detection over large-scale and bespoke, selected sources of intelligence.

This present technology enables the simulation and development of strategic and hedging options and their monitoring over time in the context of constantly changing operating environments. It utilizes the relationships between politics, economics, cultural analysis, the natural world, emerging scientific discoveries, and breakthroughs within a single platform rather than focusing on risk alone. Cultural shocks are addressed by detecting and identifying tipping points and codifying them in simulation terms to reflect uncertainty.

For example, the present technology first detects and monitors scientific research into tipping points, their momentum, and sentiment while focusing on relevant intelligence detected amongst stakeholder groups and their responses to new information. The design integrates tracking of the responses, say, of political leaders, UN institutions, and climate activists, delivering insight into possible future shifts or shocks in cultural and political terms, giving early warning of policy shocks. By focusing on the relationships between scientific discoveries relating to rapid ice melt and societal responses, the invention can capture the invention gap between emerging realities, such as rapid changes in sea levels, and policies that may mitigate the risks.

In contrast to existing state-of-the-art approaches, the present technology integrates multiple selected, specialized, and unique sources of data, intelligence, and the output of algorithmic artificial intelligence within both simulation matrix models, such as multiple, interlinked models, and morphological space and closed loop diagram (CLD) models. It is designed to adapt flexibly such that it can incorporate the output from multiple technologies, including but not limited to natural language processing and psychological profiling methods such as the Linguistic Inquiry and Word Count (LIWC), or integrative complexity models within a single navigational, early warning, and alerts framework. Unlike existing methods, the present technology allows for the selection of the best and/or multiple competing sources of data and information such that the system maintains state-of-the-art and evidence-driven predictive quality and performance and incorporates third-party or contributors within the framework that may consist of specialist sources and algorithmic output.

The utilization of discrete simulations at multiple system levels, which are not limited to simulations dictated by historical reference, can facilitate the identification of and emergence over time of low probability, high-risk events, and outcomes that otherwise tend to be excluded from traditional predictions. Many shocks cannot be identified or measured by probability. This provides a more comprehensive, systematic, and accurate prediction and analysis of emergent or possible future events and outcomes. Likewise, the simulations may identify many different paths to the same or similar results.

Utilizing simulations that are not restricted to considering the recurrence of historical events provides improved prediction accuracy and the ability to identify low probability, ‘unknown unknown’ or ‘black swan’ events, which are commonly known in broader terms as ‘radical uncertainty’, where there is no prior data or evidence and uncertainty, where probabilities cannot be estimated. Collecting additional data and performing a risk assessment for identified low-probability events based on the collected data provides improved accuracy of potential outcomes, including their emergence, momentum, and likelihood based on the simulations and the available data. The data may further be arranged into narratives to improve communication of identified hazards and their risk to decision-makers.

predicted outcomes are identified by simulations, which are be performed via simulation models. A simulation model is in some embodiments a pure simulation that is not reliant on prior evidence. The models act as ‘sentinels’. In some cases, the simulation models ‘watch’ for any sign of emergence and issue alerts. The absence of prior evidence allows simulation models to avoid issues related to bias in historical data, which trends simulation results towards repeating past simulations without adequately considering other possibilities that may be considered less probable based upon historical precedent. This includes consideration of more extreme outcomes, which might otherwise be considered highly unlikely.

Novel systems not dependent on historical data may further provide insights into how different simulations and outcomes may be interconnected. For example, if increasing drought conditions are identified based on changing weather patterns due to a dam, the design of the dam may be changed to lessen the impact, particularly to regions that may be sensitive to water loss, such as if water is being supplied to cool a nuclear power plant. Likewise, when considering a war or military action, it may be possible to consider the consequences of military action more carefully. For example, during World War II, destroying dams was a tactic used by the Allies; however, determining the impact of such actions is of increased importance, as reliance on electricity is critical to sensitive targets such as hospitals and loss of water to a nuclear power plant could lead to catastrophic outcomes.

By definition, while many future events have precedents and follow patterns, many are entirely novel and are the product of system dynamics, such as errors of judgment by leadership teams, blind spots, secret inventive developments, and many other phenomena. These are primary sources of shock and surprise because they are uncodified, so there is no data or information, and so are undetectable in searches of large-scale sources of information, such as the internet. This means they are primary sources of emerging risk and catastrophic events. They are also the primary sources shocks and of cascading, inter-systemic events that may follow shocks and will be more severe because preventive, pre-emptive, anticipatory contingency plans either do not exist or are not enacted in time to avert disaster. The Houthi attacks on Red Sea shipping is a recent example. For example, Covid-19 was predicted by some, but not all. The Russian invasion was ‘predicted’ or at least recognized as a threat by US intelligence and warnings issued, largely in secret.

Distinctions are made between well-defined, evidence-based, and near-certain emerging risks, events, discoveries, developments, etc. Uncertainties may be defined in one implementation as weak signals where predicted outcomes and future outcomes are contested, with competing views and interests, leaving outcomes unpredictable, where momentum and salience are key, and where emotion and sentiment act as early indicators. Wild cards are well-defined, often certain events, where the only uncertainty is timing. Covid-19 and major earthquakes expected on the north-west coast of the United States are examples. System dynamics comprise non-linear feedback loops, novel relationships, and cascading events can emerge spontaneously. Events are hidden, latent, and crystallize in new connections and interdependencies to generate new causal relationships and networks. Imagined futures are cultural realities and are sometimes detected through narrative expressions or may be uncodified and secret. Encoding such secrets contained within imagined futures has the potential to identify shocks and surprises well in advance and at the earliest sign of detection. This provides the basis for simulation models to predict outcomes where there is otherwise no data or evidence.

Codifying and monitoring, over time, emotional responses to possible future developments, such as climate change or fears about artificial general intelligence, forms a key role in the present technology. As does codifying cognitive tension, over time a key indicator of uncertainty. The present technology imposes these narrative structures, together with forward-looking or future language, in the form of intelligent agents that operate throughout the system. The agents seek out similar emerging stories, monitor their development over time, and automatically update similarly structured stories that form sequences of events, cascading consequences, and actions.

The present technology addresses the limitations of current practices, incorporating and building on earlier work and integrating third-party services, contributions, and other artificial intelligence sources and systems. The present technology introduces multiple novel principles and steps, including encoding key system variables within and between systems, sufficient to describe the behavior of the dynamics of the systems, that may be interconnected as they emerge over time. The model is flexible and may be applied to any complex adaptive system.

The present technology simulates, detects, and encodes, in algorithmic form, predicted outcomes and prediction estimates (sometimes referred to as ‘intelligence estimates’) and emerging, competing, and conviction narratives within a simulation matrix and/or closed-loop diagram framework. The navigational structures are specialist, novel types and variations of morphological spaces designed to codify uncertain outcomes and imagined futures over time, monitoring data and narratives in real-time from curated sources as they develop. The narrative models focus on codifying, exploring, and actively monitoring system-critical uncertain variables and simulated endgames or outcomes over time. These are codified in the form of stories, which represent imagined futures and are indicators of salience and meaning. Stories are vital to predictive value since they can capture possible outcomes and represent changing emotional journeys in relation to themes like climate risk over time. They can capture salience over time and create structure and shared understanding beyond abstract principles. Unlike data and information, stories are not limited by past or current events or real-world developments. They can represent uncertainty, contested futures, future novelties, and project extreme endgames. Narratives are encoded in the form of bespoke future-oriented stories that act as search strategies operating over large-scale sources of data and intelligence, curated, and selected by specialists. All stories have structure. The invention focuses on the middle, defined by rising tension the convergence or coincidence of multiple ‘threads’ and uncertainty, and the end, which comprises the resolution of uncertainty.

The same principles are applied to identify, monitor, and evaluate emerging scientific discoveries, and systemic innovation, where the sum of the combination of inventions may create novelty beyond the sum of the parts. Again, the invention focuses on imagining future states, looking forward, and asking what-if questions. The coded narrative that captures possible future scientific discoveries and inventive breakthroughs is then tracked to highlight whether the outcome is emerging. The key difference between the present invention and existing art is that it integrates the emergence of scientific discovery and breakthrough invention to transform systems over time, a fundamental flaw in current practice. Radical innovation is inseparable from system evolution and dynamics, yet in risk-oriented attempts to model inter-systemic risk, little or no account of how scientific discovery and radical invention may slow, stop, or change the course of cascading failures before they gather momentum, how policy or other interventions may accelerate the development and roll-out of breakthrough inventions, or how multiple inventions from diverse scientific and inventive domains may be integrated to transform system relationships between variables. The prospects of scientific discoveries and breakthrough inventions also have an impact on short-term decision-making and policy judgments despite the uncertainty. The present technology reduces the uncertainty surrounding these archetypical imagined futures, but also systematically links needs with potential solutions.

The system is designed to define future needs and then direct investment in invention. This is illustrated in the development of the Moderna vaccine, which began in 2013 within DARPA when a program manager raised two questions with the leadership team. What if a novel pathogen causes a global pandemic that forces the world to stand still, and we can't wait years for a vaccine? And what if mRNA injected directly into the body to elicit vaccine-level antibody production could dramatically shrink the standard timeline for vaccine development? The result, a decade later, was the Moderna vaccine that played a major role in Covid-19 treatment around the world. The invention is designed to anticipate future needs through the simulation framework matrix, map intelligence against those needs, look for invention gaps and ‘white space’ (where there are possible future needs but no inventive activity or possible solutions) and then provide decision-makers and investors with the methods and tools by which they can direct and prioritize resources to future needs that may be environmental, economic, or financial.

The present technology detects and monitors neurobiological responses to ideas over time, making the distinction between emotion, which we define as immediate; mood, which is transitory; and feeling, which persists and evolves over time. The present technology maps and projects imagined future scientific discoveries in the context of the simulation matrix. The present technology monitors for emergence through measures of momentum, language, and competing narratives. A key indicator of uncertainty is the detection of cognitive tension in language, illustrated by models such as the Linguistic Inquiry and Word Count (LIWC).

Human communication is about relevant intelligence and dynamic relationships in all spheres of knowledge, including science, and is based on or expressed in narrative models and stories, such that changes in and between stories are key indicators of system dynamics. Imagined futures are both innate human characteristics defined by perpetual observation, knowledge-seeking and simulation, and cultural realities that shape decisions in the present and are subject to examination and revision over time.

Genuine stories follow similar structures and anchor belief systems and emotional responses to possible future events over time. They ‘search for an ending’, rather than converge as ‘fact’, conveying uncertainty, possible outcomes, or ‘open futures’ instead. Stories reflect real-world and human experience, given we face perpetual, unceasing uncertainty. Codifying and monitoring—over time—emotional responses to possible future developments, such as climate change, or ‘fears’ about artificial general intelligence (AGI) forms a key role in the preferred system/method. As does codifying ‘cognitive tension’, again over time—a key indicator of uncertainty. Relationships to imagined futures, such as projected scientific discoveries, shape short-term decision-making, and are subject to contention and competition, and indicate the direction of outcomes over time. This means that detecting changes in the scientific literature and patent landscape is critical.

Detection, identification, and codification of emerging risks and opportunities is distinct from historical modeling. Simulation models for ‘unknown unknowns’ are pure simulations, where there is no evidence, theory, or story, and act as ‘story agents’ designed to identify the emergence of the first detection of emerging risks. Predicted outcomes associated with weak signals are typically characterized by ambiguous, contested, and uncertain outcomes, where there is evidence but no clarity about endgames. Wild cards are high-certainty events, such as a pandemic like Covid-19, but the timing is uncertain. Algorithms are used to capture and codify forward-looking, narrative prophecies or future projections and extract future-oriented language, as well as the explicit and implicit narratives that explore possible outcomes. Some ‘story agents’, such as, for example, a key early indicator of policy failure such as ‘too little, too late’ in relation to climate change are applied throughout the system. ‘Too little, too late’ and a library of similar terms search in multiple domains, beyond climate risk where the story has high momentum, such as artificial intelligence safety.

The present technology may map protagonists and their relationship to specific themes, such as drought, or sea level rise associated with island states. These relationships are codified according to emotional and cognitive responses, such that beliefs and intentions are tracked over time. These relationships form a predictive model and early warning system. These relationships may be extracted, for example, from speeches delivered by world leaders, and may be codified and analyzed for individual emotion, cognitive response, and the individual's past and future orientation. The analysis may provide statistics that may be compared to previous speeches delivered by the individual, revealing changes in their beliefs over time. The analysis may additionally indicate changes over time within a standard psychological map of valence and arousal, pleasure vs displeasure, or high versus low excitement. The changes over time may further be mapped. Likewise, differences in language and narrative between world leaders may be compared. Each variable may be mapped and compared over time to demonstrate system dynamics and highlight emergence.

Imagined futures and multi-factorial scenario outcomes are captured within a navigational framework in the form of a simulation matrix, a specialized form of multi-variant, immersive futures morphological space, and closed-loop diagrams. The variables are applied in multiple fields and are universal, whether the simulation focus on political, climate, policy, market, financial, economic-related futures, or future breakthrough inventions.

Political beliefs are shaped by narratives representative of simplified causal models representing long-run correlations. When presented with competing narratives, people are sometimes drawn to narratives that promise happy endings, or to fears and threats, which tend to be subjective based on each individual. Narratives can be more convincing than statistical information, even when the variables are shown to be independent. Narratives appeal to emotion, create engagement, and create a lens to interpret causal relationships in data. This means narrative and story are more relevant in describing uncertainty and dynamic relationships between variables than science and statistical methods. They are also more easily communicated and more effective in creating share understanding in social, cultural and political groups, at all levels. The invention encodes stories as ‘story agents’, (intelligent software agents) as search strategies and directed acyclic graph-based causal narratives and imaginative narratives in algorithm-driven natural language processing software that searches large-scale and curated specialist sources of data, information, and intelligence. The stories and each node in directed acyclic graphs are expressed first as stories, then as search strings, embodied in one embodiment, in Boolean search (or specialized, future-oriented LLM prompts) terms, and forming the basis for trained classifiers, say in the form of specialized families of stories and terms applied to say military threats, or diplomacy.

In some cases, the search terms may be provided to one or more of natural language processing models and/or a large language models. For example, drought may be codified in specific narrative directed acyclic graphs to make the distinction between water shortages and chronic, multi-year droughts that represent existential risks. The system monitors each variation and each possible outcome, over time. The narrative directed acyclic graphs may be expanded in infinite variations, from single words to long storylines, such that they can accurately capture the theme, system variables, and emergence over time and responses to system dynamics. The stories, directed acyclic graphs, and classifiers may be designed by specialist domain experts. The search algorithms are trained and retrained using specialist sources pre-screened for accuracy, information integrity, and quality. This invention combines natural language processing techniques and algorithm training with specific applications of software that detect emotional signatures, stress, and uncertainty about future outcomes in narratives. The narratives are encoded in algorithm form as search criteria, the results of which are measured by frequency over time to determine momentum and the strength of emotional commitment, from uncertainty to conviction, specifically in relation to events or possible future events. The narratives focus on future states, language, and words that point forward, express uncertainty, and highlight cognitive tension or convictions about outcomes. Each narrative codifies the cognitive tension and emotional response in media and information services in relation to emerging risks as they gather pace and tension and gain momentum and salience.

The present technology may focus on key protagonists and their language and intent about particular themes or emerging narratives. These may be political, financial, or investment leaders. Narrative analysis is particularly valuable as a source of intelligence about future political, policy, and regulation shocks and tipping points because policy is expressed and debated in the public domain. Leadership teams tell stories, exhibit emotion, and reveal values and attitudes, which are predictive of intent and emergent social behavior. In one embodiment, analysis of propaganda reveals intent of world leaders. Corporate leaders, both through forward-looking submissions to regulators and in public statements to shareholders, reveal their cultural values in relation to emerging risks. This is particularly important in relation to climate change, given the increasing risks of legal action. Their emotional and cognitive responses to emerging catastrophic risks, policy interventions, and breakthrough ideas are all important sources of intelligence.

The system and methods taught herein could be said to provide a clear view of present and emerging futures, preferably implemented as a dashboard through which an operator is able to see not only present-day situations but to simulate and monitor the dynamics of evolving and emerging complexity and uncertainty over time within a complex adaptive system.

### DETAILED DESCRIPTION

Embodiments of the present disclosure will be described more fully hereinafter with reference to the accompanying drawings in which like numerals represent like elements throughout the several figures, and in which example embodiments are shown. Embodiments of the claims may, however, be embodied in many different forms and should not be construed as limited to the embodiments set forth herein. The examples set forth herein are non-limiting examples and are merely examples among other possible examples.

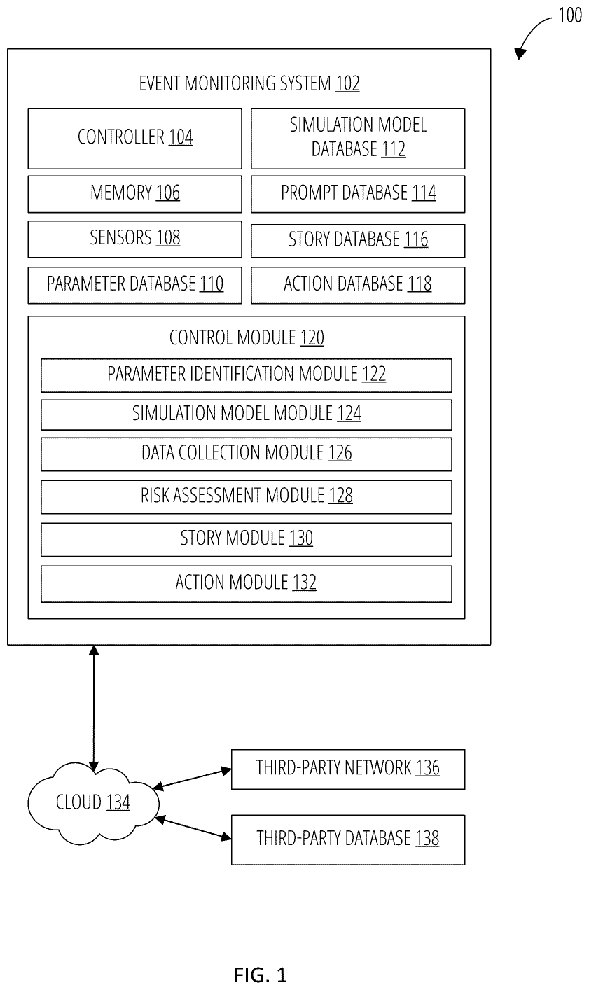

FIG. 1 illustrates a system for a risk management system.

The risk management system 100 may comprise of an event monitoring system 102, which may be a computer system that utilizes a controller and memory to monitor, analyze, and react to present and future events. The event monitoring system 102 may collect data from sensors 108, third-party networks 136, and third-party databases 138. The collected data may be used to train artificial intelligence models for the purpose of performing simulations and making predictions of the possibility or likelihood of events or outcomes occurring. The event monitoring system 102 is a system for simulating, modeling, mapping, detecting, identifying, codifying, monitoring, and navigating emerging risks particularly system-level and inter-systemic, catastrophic risk, scientific discovery, and systemic innovation in complex adaptive future environments.

The event monitoring system 102 delivers results of automated or semi-automated intelligence gathering of emerging events and risks in the form of news stories, alerts, and expert analysis and a dashboard that displays a system-level macro view of multiple, live events that simulate development over time. The event monitoring system 102 integrates both model first and model-free approaches to the use of artificial intelligence (AI) in order to overcome the limitations of conventional risk management systems. It also overcomes the limitations of large language models and machine learning systems that rely on historical data and patterns to create predictive models, products, and services. It is also designed to counter human failures of the imagination and blind spots that characterize many catastrophic events, from 9/11 to the Challenger disaster and the cascading events that began with the 2008 financial crash or the Russian invasion of Ukraine.

The event monitoring system 102 is based on a system of representation that encompasses not only facts and hard evidence but also intangible, uncodified, novel, or imagined future outcomes that may crystallize to reshape present realities as well as future worlds. These uncodified outcomes are simulated both by experts and by the neural networks within the system. This contrasts with conventional risk and strategic innovation methods that are dominated by evidence and so are blind to shocks. Imagined futures, while intangible and uncodified, are cultural realities that shape decisions and influence outcomes in everything from political ideologies to science and technological innovation. They set agendas, even when fictional or unrealistic. They determine real-world behaviors and outcomes. For example, residents of Miami will move when the imagined future narrative shifts from “we can adapt our homes to subsidence, storm surges, and hurricanes” to “parts of Miami will become uninhabitable.” The event monitoring system 102 is designed to model, simulate, and mirror a deeper world where clandestine or secret activity is hidden from view and then report its emergence at the moment of transition from unknown unknown to intelligence alerts and codification.

The event monitoring system 102 creates the system-level context within which to develop policy interventions and set strategic invention objectives, setting requirements in context. This reflects the reality that many investments in invention become redundant or are devalued when market, scientific, or strategic agendas and needs change. By anticipating uncodified and unarticulated future needs, the event monitoring system 102 can pinpoint and simulate future needs and then compare those needs to existing or emerging scientific or inventive activity, identifying gaps, or foresight-defined white space. The event monitoring system 102 is designed to counter the failures of imagination that are well documented in the literature of extreme catastrophic events. The event monitoring system 102 is designed to deliver predictive intelligence that allows users to simulate causally linked cascading events, as well as possible events that may only be related in time and events that may become related in time. The novel design allows users to represent and simulate how extreme what-if or worst-case developments may emerge and how tipping points may drive cascading impacts through systems, creating unexpected shocks. This facilitates the reduction of risks associated with surprise.

The event monitoring system 102 codifies and monitors key indicators and predictive values through detection and measures of momentum, cognitive tension, and emotional response within stories and narratives. These measures are applied to emerging risks, scientific discoveries, and breakthrough innovations. In some cases, the emotional response of political leaders to public concerns about wildfires may be detected, together with their authority and confidence to reduce future risks, and tracked for momentum over time. The invention detects and enables the interpretation of primary emotions and behavioral responses to future or imagined future events.

The codification and monitoring of the dynamics of these relationships are a source of intelligence and early warning. Imagined futures and the narratives that express them amongst individual and group protagonists, together with their emotional responses to emerging narratives, event dynamics, and weak, ambiguous signals of emerging events are captured. The changing dynamics within narratives, as well as relationships between narratives, may be defined, detected, and interpreted by their a priori causal connections, emerging connections, and by language, metaphor, and story-linked cultural belief systems and ideological worldviews. Weak ties between stories, their momentum over time, and novel relationships, such as, for example, between extreme drought, water supplies, emerging risks to nuclear installations, and hydropower, may be identified. In some cases, the event monitoring system 102 may detect and monitor a president's changing attitude to climate risk over time.

The event monitoring system 102 applies novel approaches to detect early warning signals by scanning narrative dynamics within large-scale sources of content. It also integrates and extends third-party systems, such as emotion detection and cognitive tension measures, in the application of future-oriented search strategies. The event monitoring system 102 may be used in early warning systems, as a simulation system as a model to stress test existing strategies and/or as the basis for the development of strategic options and hedging models. It may be used in intelligence, policy development, investment analysis or in shaping innovation development.

Simulations performed by the event monitoring system 102, such as by simulation models, as well as early detection, codification and monitoring of predicted outcomes are key to understanding emergence in complex, open, adaptive systems and to crystallizing imagined futures and the narratives that express them. Automated alerts are delivered in response to the first detection of the defined micro narrative. simulation models are the precursors of predicted outcomes. predicted outcomes of emerging or possible threats are characterized by ambiguity, competing narratives and cognitive tension exhibited in language and detected by the language used in relation to nascent themes, such as the fragility of power infrastructures in extreme drought. predicted outcomes are detected, codified, tracked for momentum, and interpreted in narrative form by bringing together special domain expertise and specialist sources. Relationships between predicted outcomes are a key indicator of changing system dynamics.

In some cases, the event monitoring system 102 detects and identifies new words, stories, conceptual or linguistic or cognitive framing, or categories as predicted outcomes and defines a search string to monitor for emergence and momentum. The event monitoring system 102 focuses on uncertainty, multiple pathways, and momentum of one or more outcomes, consistent with the simulation matrix. The simulated predicted outcome is the initial reference point, model, or anchor for the algorithm design and search. The predictive value is derived from proximity to the story, or momentum towards a story ending.

The search focuses on uncertainties associated with the predicted outcome story, such as contested views, levels of cognitive tension amongst say world leaders in relation to the individual predicted outcomes, or for example the “too little, too late” simulation, and emotional responses to the predicted outcome or macro theme. The search may additionally focus on proximity to the predicted outcome story, endgame, or outcome, and momentum towards or away from the simulation or predicted outcome. The search strategies look for similarity to the model in the language terms and storylines. If the results point towards the model, then this has predictive value, and the simulated narrative model is emerging as more likely over time. In contrast to information, in fictional, there is no explanation or convergence around an ending, but rather a search for an ending, for an outcome and a resolution of uncertainty. All possible outcomes co-exist, each as latent and hidden possible future events and timelines. The event monitoring system 102 mimics this structure, given that the real world and fiction share uncertainty that is only resolved over time.

Further, embodiments may include a controller 104. A controller is a logic device that executes algorithms to transform input data into output data. The transformation comprises a series of calculations typically executed in binary, where each discrete component of data comprises one of two states, high or low voltage, typically represented as a 1 or 0, respectively. A controller 104 is typically comprised of semiconductor materials arranged upon a silicon substrate. In some embodiments, a controller 104 may refer to a centralized processing unit (CPU) or a graphical processing unit (GPU). In some embodiments, a controller 104 may be optimized for artificial intelligence applications, such as by optimizing for parallel processing. In some embodiments, a controller 104 may refer to the processing components in a quantum computer.

Further, embodiments may include memory 106, which is a data storage device. Memory 106 may be persistent or volatile. Volatile memory, such as random access memory (RAM) in a computing device, requires power to maintain data, with the data being lost when power is not provided. Persistent memory 106 retains data even when not powered on. Memory 106 may be solid state, such as in flash storage, or may use mechanical storage, such as mechanical hard drive disks (HDD). Memory 106 may comprise a standalone component or may be integrated into devices such as a controller 104 as a cache.

Further, embodiments may include sensors 108, which are devices for detecting and measuring physical properties such as temperature, force, motion, pressure, heart rate, blood oxygen concentration, etc. For example, sensors 108 may include thermometers, thermocouples, bolometers, hall probes, strain gauges, load cells, accelerometers, pulse oximeters, etc. In some cases, a sensor 108 may comprise an accelerometer or a global positioning system (GPS) transceiver to determine a vehicle's location and movements.

Further, embodiments may include a parameter database 110. A parameter database 110, with an example shown below, stores parameters extracted from structured or unstructured data, which may be used to identify relevant simulation models.

| ID | Source | Field | Data |
|---|---|---|---|
| 1 | Insurance Contract | Contract Start Data | Apr. 8, 2024 |
| 2 | Insurance Contract | Expiration Date | Apr. 17, 2024 |
| 3 | Insurance Contract | Policy Terms | Variable Rate |
| 4 | News | Headline | Houthi Rebels Attach Red |
| | | | Sea Shipping Lanes |
| 5 | News | Parties | Yemen Houthi Rebels, US Navy, Israel |
| 6 | News | Impact | Economic and Logistic Disruption |
| 7 | News | Data | Apr. 10, 2024 |
| 8 | News | Parties | Israel, Hamas |
| 9 | News | Event | Drought |
| 10 | News | Event | Wildfires |

The parameter database 110 stores data comprising identified parameters extracted from structured data, such as an insurance contract or specified risk event, such as a scientific breakthrough. The parameters may be received from the parameter identification module 122 and may comprise data received from a user, third-party network 136, or third-party database 138. In some embodiments, the data stored in the parameter database 110 may be populated directly by a user of an event monitoring system 102 or by a third-party network 136, such as via an application programming interface (API). The data stored in the parameter database is used by the simulation model module 124 to identify relevant simulation models to be activated to perform simulations in search of predicted outcomes.

Further, embodiments may include a simulation model database 112, which stores simulation models, which are simulations that may be activated based on one or more parameters. In some cases, simulation models are ‘pure’ simulations, with no previous or historical precedent, or ‘imagined futures’, unaffected by external data and perform simulations based on narrowly prescribed initial data. The simulation model database 112 may additionally store simulation results, including predicted outcomes. Predicted outcomes or intelligence estimates are low-probability outcomes that may have significant impacts, such as events referred to as black swans. These events tend to have a high certainty of occurring; however, they have a high degree of uncertainty in terms of predictability of exactly when the events will occur. An example simulation model database 112 is shown below.

| ID | Description | Parameters |
|---|---|---|
| 1 | Red Sea Shipping | Apr. 8, 2024-Apr. 17, 2024, Red Sea, Shipping |
| 2 | Middle East Violence | Apr. 8, 2024-Apr. 17, 2024, Houthi Rebels |
| 3 | US Navy Operations in Red | Apr. 8, 2024-Apr. 17, 2024, Red Sea, US Navy |
| | Sea | |
| 4 | Climate Conditions South | Climate, South Pacific, Sea Level, |
| | Pacific | Weather |
| 5 | Autonomous Drone Swarms | Drone, Swarm, Weapon |
| 6 | Drought in Southeast Asia | Drought, China, Vietnam |
| 7 | Dam Breach in China | Dam, River, China, Reservoir, Flood |

The simulation model database 112 stores simulation models, which are digital models used to perform simulations when activated by matching one or more relevant parameters. The simulations performed by the simulation models are unaffected by external data but act as reference models to track momentum and proximity. While the simulation models may be the product of machine learning models, they are not subject to further training data or input data once activated, and they are performing simulations. In some embodiments, external data may be provided in the form of an initial set of expert-defined parameter data, information or stories, or simulated futures, which are used by the simulation models to perform simulations.

The parameters utilized by the simulation models may include variability, which may be used in conjunction with repetition to determine a probability representing the likelihood of or momentum towards an event or outcome. In one novel application, the simulation models form a large-scale library of extreme possible events that may emerge over time. Such events, sometimes called black swans or unknown unknowns are elusive and remain uncodified in conventional risk systems. They are latent, hidden, or emerge spontaneously in the dynamic interactions between objects, people, and events within complex adaptive systems that define the real world. They have no historical precedent or emerge from dynamic interactions between systems, people, or objects.

Simulation models may be linked together to form an array, or network, or take the form of a live updated knowledge graph that shows existing, emerging, novel, new, or latent sets of relationships, such that a simulated future relationship is defined and itself becomes a further simulation model that represents a combination of events or developments. The simulation models are designed to meet specific design criteria and define specific alert conditions. In other words, simulation models are codified and modified, and report to the editors when pre-defined conditions are met. Simulation models and the relationships between them are trained through neural networks, such that training models form part of the search strategy and design and are themselves autonomous within the event monitoring system 102.

They are trained to find patterns that may, for example, be a simulation of a terrorist attack or a military incursion about which there is no pre-existing intelligence. Simulation models are designed to detect, in advance, the possibility and the evolving reality, for example, events such as the Houthi attacks on shipping in the Red Sea in December 2023 about which there was no news or prior warning. These may represent a latent connection that may, in certain system conditions, crystallize and gain momentum over time. These relationships may be predefined from expert judgment based on models of how the world works, in the form of but not limited to causal relationships, belief systems, and narratives based on historical evidence.

Simulation models further comprise simulated or micro-simulation relationships between imagined futures and interactions between events, people, places, and objects where there may be no evidence. This allows the design to represent possible future events, emerging narratives, predicted outcomes, system emergence, trigger points, causally related cascading events, scientific discoveries and breakthrough inventions in complex worlds and information networks. The simulation model database 112 may additionally store predicted outcomes, which are events or outcomes with a low probability of occurring, but which may pose a significant risk. In some embodiments, a predicted outcome may comprise a trigger condition that may have a low probability of resulting in a significantly consequential event or outcome.

Further, embodiments may include a prompt database 114 which stores prompts for use by a large language model and/or natural language processing system. The prompts may additionally comprise a request component that describes what the large language model should return as a response. The prompts may be user-generated or may be generated by a large language model or another artificial intelligence model. Communication with a large language model, such as those provided by a third-party network 136, may be achieved via an application programming interface. In other embodiments, prompts may be submitted directly to a large language model hosted by a personal event monitoring system 102. See below for an example prompt database 114.

| Module | Information Component | Data Source | Request Component |
|---|---|---|---|
| Data Collection | Considering the | Predicted | Provide a list of news articles |
| | predicted outcome: | Outcome | relating to the predicted outcome |
| | [data] | | |
| Data Collection | Considering the | Predicted | Provide a list of references which |
| | predicted outcome: | Outcome, | include the provided data |
| | [data] | Parameters | |
| Data Collection | Considering the | Predicted | Create a search query to be |
| | predicted outcome: | Outcome | submitted to a search engine to |
| | [data] | | find relevant references |
| Store Module | Using the predicted | Predicted | Generate a hypothetical story |
| | outcome: [data] and the | Outcome, | describing the provided |
| | collected data: [data] | Collected Data | information |
| Store Module | Using data from the | Predicted | Provide a summary of events |
| | collected data: [data] | Outcome, | according to the correlated data |
| | matching the predicted | Collected Data | |
| | outcome [data] | | |
| Store Module | For the predicted | Predicted | Create a timeline of notable events |
| | outcome [data], use the | Outcome, | |
| | simulation model results | Simulation Model | |
| | | Results | |

The prompt database 114 stores prompts to be used by a large language model or natural language processing system. The prompts may comprise an information component that refers to a source of data, such as a parameter database 110, simulation model database 112, story database 116, action database 118, third-party network 136, third-party database 138, etc. The prompts may additionally comprise a request component that describes what the large language model should return as a response. The prompts may be user-generated or may be generated by a large language model or another artificial intelligence model.

Communication with a large language model, such as those provided by a third-party network 136, may be achieved via an application programming interface. In other embodiments, prompts may be submitted directly to a large language model hosted by an event monitoring system 102. The prompt database 114 may be populated manually by a user or, alternatively, by a large language model and/or natural language processing system. The prompts in the prompt database 114 may be updated by a large language model using data collected by the risk assessment module 128, story module 130, or the action module 132. The prompt database 114 is used by the data collection module 126 and the story module 130.

Further, embodiments may include a story database 116, which stores stories and supporting data. Stories may comprise narrative form accounts and descriptions of factual events or fictional future events. The story database 116 may additionally store data referenced by stories. An example story database 116 is shown below

| ID | Story Description | Narrative ID-Order |
|---|---|---|
| 1 | Houthi rebels attach ships in Red Sea | 1-2 |
| 2 | Israel attack Hamas in Gaza | 1-1 |
| 3 | US Navy Patrols Red Sea | 1-3 |
| 4 | US Navy shoots down Houthi missiles | 1-4 |
| 5 | Western US reservoirs at record low | 2-1 |
| | levels | |
| 6 | Largest wildfires in Texas History | 2-2 |
| 7 | Hundreds of uncontrolled fires in | 3-2 |
| | Canada | |
| 8 | Permafrost thawing in Northern Canada | 3-1 |

The story database 116 stores data related to one or more stories and narratives that describe past and hypothetical future events. The stories may comprise a combination of factual and fictional data. The story database 116 is populated by the story module 130 and may be used by the story module 130 and the action module 132. The data stored in the story database 116 may be generated using one or more large language models and/or natural language processing systems. That data stored in the story database 116 may additionally be sourced from or reference data from any of the parameter database 110, simulation model database 112, prompt database 114, or story database 116. The data may be stored in a variety of formats, including text, audio, images, video, data tables, etc.

In some cases, the story database 116 may comprise a specialist library of extended narrative and directed acyclic graph combinations, including initial conditions, trigger events to cascading series of outcomes and endgames, and intermediary narrative components and/or events. Directed acyclic graphs and causal narratives may not define static or reliable causal links but instead dynamic, emerging relationships that change over time. The combined narrative, directed acyclic graph, and algorithm sequence trained and validated by specialists are defined as a package and matched to specific sources selected to optimize their predictive value. In an embodiment, the sequence and source selection package form part of a library tailored to specific sectors, such as energy, or regions, or emerging risks, such as potential tipping points that may relate to multiple sectors.

Further, embodiments may include an action database 118, which stores actions and action criteria, which are trigger conditions, which, when satisfied, cause the corresponding action to be executed. The action database 118 may additionally store data related to applicable stories and any other conditions relevant to the actions. In some embodiments, the action database 118 may store previously executed actions, when the action was executed, the conditions satisfied that caused the action to be executed, and any other information relevant to the action or story that triggered the action. An example action database 118 is shown below.

| ID | Action | Action Criteria |
|---|---|---|
| 1 | Send alert to notification list | Likelihood of occurring >75% |
| 2 | Increase insurance rate by 50% | Projected casualties >1 |
| 3 | Decrease insurance rate by 25% | Ship diverts from high risk region |
| 4 | Revoke insurance policy | Ship ignores diversion request |
| 5 | Advise diversion to alternate route | Projected fatalities >1 |
| 6 | Request additional resources | Wildfires growing by >1000 |
| | | acres/day |
| 7 | Restrict water usage | Drought conditions persist >3 months |

The action database 118 stores actions and action criteria comprising one or more trigger conditions for each action such that when the trigger conditions are satisfied, the action is executed. The action database 118 may additionally store executed actions. The action database 118 may be user-generated or may be generated by a large language model, natural language processing system, or another artificial intelligence model. The action database 118 is used by the action module 132.

Further, embodiments may include a control module 120 that initiates a parameter identification module 122 that receives structured data and receives one or more parameters identified from the received structured data. The simulation model module 124 is initiated, which selects simulation models related to the identified parameters that perform simulations and from which simulation results, which may comprise one or more predicted outcomes, are received. The data collection module 126 is initiated which generates one or more queries based upon the received simulation results and from which query results are received. The risk assessment module 128 is initiated, which determines the risk associated with each received predicted outcome using the parameters, simulation results, and additional collected data and from which at least one risk assessment is received. The story module 130 is initiated, which uses a large language model and/or natural language processing system to generate a narrative based on at least one predicted outcome using the identified parameters, simulation results, collected data, and risk assessments.

Each narrative and algorithm may include micro-simulations, stories, or models. Models may define well-known causal relationships defined by precedent, as in academic literature, simulate events, developments, and relationships where there is no prior data or evidence, sometimes referred to as unknown unknowns, or as simulation models. Narratives may be arranged within a macro simulation matrix, where multiple predicted outcomes may be described in the form of narratives and arranged in directed acyclic graphs. Narratives may include macro, system-level representations, and highly specific simulated outcomes over time. The simulation matrix is both the initial model and a real-time dashboard that is populated by the live output from an automated search of predicted outcomes and simulation models, which in both cases deliver alerts to a change in condition, defined by criteria such as momentum, novelty or surprise, or changes in sentiment.

The action module 132 may be initiated, and actions with criteria matched by the data included in or associated with the narratives received from the story module 130 are executed, and the executed actions are received. If ongoing monitoring is necessary, the process is repeated. The results of monitoring and alerts within the system may create one or more dashboards representing system dynamics, the emergence of novelty and alert mechanisms, and news about the future. The system enables simulation of future events, early warning of the maintenance of a live dynamic simulation matrix dashboard. When no further monitoring is necessary, the event monitoring system 102 ends.

Further, the control module 120 may include a parameter identification module 122. The parameter identification module 122 receives structured or, alternatively, unstructured data from which structured data may be extracted. One or more parameters are identified from the extracted data which are saved to the parameter database 110. The identified parameters are sent to the control module 120.

Further, the control module 120 may include a simulation model module 124. The simulation model module 124 queries the parameter database 110 and selects a parameter from the received data. The simulation model database 112 is queried for simulation models related to the selected parameters and selects a simulation model from the received simulation models. Simulations are performed using the simulation models, and results from one or more simulations are received. The simulation results are saved to the simulation model database 112 and any remaining simulation models are selected, and simulations performed. The remaining parameters or combinations of parameters and simulation models are selected, and simulations are performed. The simulation results are sent to the control module 120.

Further, the control module 120 may include a data collection module 126. The data collection module 126 queries the simulation model database 112 and selects simulation results, which may comprise one or more predicted outcomes. A connection is established with one or more large language model networks and/or natural language processing systems, search engines, or databases, and a search query is generated, which may utilize a prompt database 114. The search query is submitted to one or more of a large language model, search engine, or database, and query results are received. The query results may further be analyzed to determine whether the query results match the submitted simulation results and may further match the simulation results to one or more identified parameters. The query results are saved to the simulation model database 112 and are sent to the control module 120.

Further, the control module 120 may include a risk assessment module 128. The risk assessment module 128 queries the simulation model database 112 for data, from which a predicted outcome is selected. The likelihood of the realization of the selected predicted outcome is predicted. Similarly, the impact of the realization of the selected simulation model or predicted outcome is predicted. A risk score may then be determined, which may comprise an aggregate score or a plurality of scores assessing different types of risk. The risk assessment is saved to the simulation model database 112. The risk assessment process is repeated for any additional predicted outcomes that are to be assessed, and the risk assessments are sent to the control module 120.

Further, the control module 120 may include a story module 130. The story module 130 queries a simulation model database 112 for simulation and risk assessment data, and the story database 116 for story data which may relate to the simulation and risk assessment data. A connection to a large language model network and/or natural language processing system is established, and a prompt is generated, which may utilize the prompt database 114. The generated prompt is submitted to the large language model from which a generated story is received. The generated story may be compared with data received from the story database 116 to identify related stories. The related stories may then be arranged into wider, deeper, or linked narratives, such as by chronologically arranging the stories or by requesting a large language model or other natural language processing system to consolidate and summarize the stories as a single narrative. The narrative is then saved to the story database 116. Stories and narratives are generated for risk assessments, which are associated with simulation models or predicted outcomes, and the generated narratives are sent to the control module 120.

Further, the control module 120 may include an action module 132. The action module 132 queries the story database 116 and the action database 118. A story and an action are selected from the received data, the story comprising a narrative and the action comprising an action and action criteria. Action criteria are trigger conditions that are satisfied by data in or associated with the selected story or narrative and cause the associated action to be executed. The executed action is saved to the action database 118. Actions are assessed for all combinations of actions and stories, and the executed actions are sent to the control module 120.

Further, the risk management system 100 may include a cloud 134 that is a distributed network of computational and data storage resources that may be available via the internet or by a local network. A cloud 134 accessible via the internet is generally referred to as a public cloud, whereas a cloud 134 on a local network is generally referred to as a private cloud. A cloud 134 may further be protected by encrypting data and requiring user authentication before accessing its resources.

Further, the risk management system 100 may include a third-party network 136 that is comprised of one or more network resources owned by another party, which may be accessible via an application programming interface (API). For example, a third-party network 136 may refer to a search engine such as Google or Bing. A third-party network 136 may also refer to a natural language processing service or large language model network such as OpenAI's ChatGPT, Google's Bard or Gemini, Microsoft's Bing, Meta's Llama, PrimerAI, etc. Each variable or part of a variable identified or utilized by the event monitoring system 102 may be delivered from a third-party network 136 or third-party database 138 comprising independent selected sources with specialist expertise, algorithm designs, or inventions via application programming interface links.

The event monitoring system 102 may be designed to ingest historical narrative data feeds or specific intelligence from multiple expert sources to automate all or part of the navigational framework or defined sub-sets. In some embodiments, sources and contributions may be licensed in the form of nonfungible tokens to guarantee copyright, authenticity, and provenance. In some cases, selected sources are displayed within a simulation matrix and integral to the alert and dashboard paradigms that apply across the system. Examples of third-party network 136 data sources may comprise live feeds of novel words as a source for monitoring emerging ideas and risks, specialist early warning systems of emerging conditions, sources of data, information, and intelligence which may be verified by a third-party such as Newsguard for monitoring editorial standards, and live feeds of legal documents such as corporate filings and patent applications.

Further, embodiments may include a third-party database 138 stores data owned by another party. For example, a third-party database 138 may store or access data on a third-party network 136, such as insurance contracts. A third-party database 138 may comprise news articles, weather forecasts, foreign intelligence, etc.

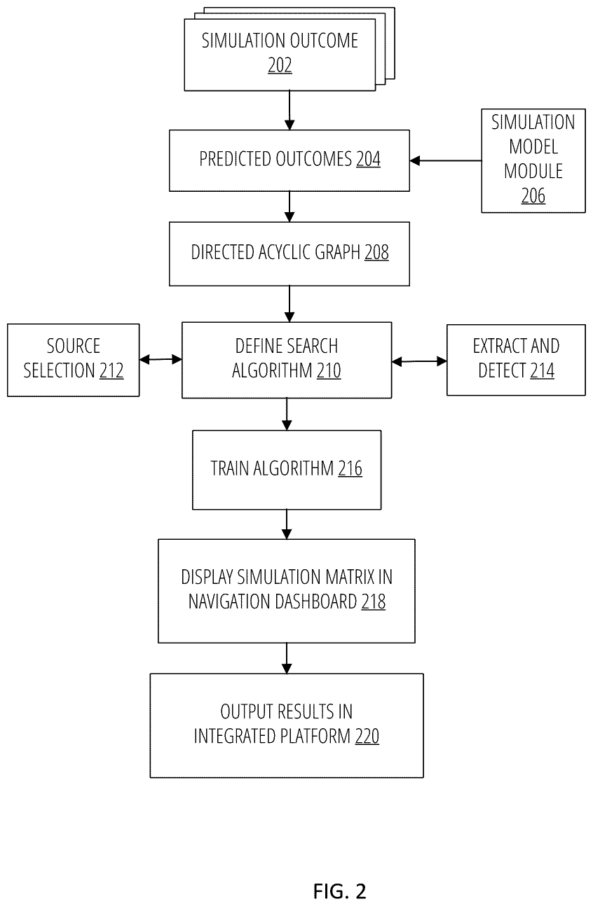

FIG. 2 illustrates an example diagram for generating a simulated outcome and displaying results in a dynamic simulation matrix dashboard.

The example diagram 200 includes providing one or more simulated outcomes 202. In some cases, the simulated outcome 202 in provided in narrative form. High-impact, high uncertainty system variables may become related, some causally, over time, such as climate crises resulting in geo-strategic disorder and resulting in inter-systemic failures. As such, there may be emergent properties and emerging narratives of the risk management system 100.

In some cases, in providing the simulated outcome 202, the risk management system 100 may simulate and define high impact and/or uncertain variables or themes representing present global system conditions and strategic landscape, such as minimum number of variables sufficient to defined sufficient to describe the system dynamic evolution over time. The variables may include political, climate, policy, market, financial, economic related or breakthrough inventions.

In some cases, simulation variables may be identified by a simulation model module 206 in which there is no historical data or prior evidence. The simulation model module 206 may be simulated and encoded in narratives and Directed Acyclic Graphs (DAGs) 208. Predicted outcomes 204 may also encoded be within the matrix for each variable, as early indicators of emerging risks or breakthrough inventions. Predicted outcomes 204 may be identified through source selection, novel language, or new categories, both in macro-relations and in breakthrough inventions.

In some cases, causal narratives may be defined by specialist judgment and source selection, encoded in DAGs 208 to define relationships between variables. Each variable or part of a variable may be delivered from independent selected sources (e.g. patent data sources and intelligence) with specialist expertise, algorithm designs or inventions via an API link. These specially selected sources may be licensed, together with selected output from the dynamic simulation matrix in the form of NFTs to guarantee copyright, authenticity, provenance, security and privacy.

In some cases, a search algorithm is defined (210) using Boolean search strings or trained classifiers to detect emotion, cognitive tension, and momentum over time. The algorithms may reveal the emerging relationships between components of the variables and the DAGs 208. For example, the significance of the relationships between drought and water shortages, identified by momentum, emotion, cognitive tension, uncertainty, and sentiment. The models may be further encoded to define search algorithms 210, which individually and together act as nested training scripts. Links between some variables may be illustrated.

In some cases, the defined search algorithm may be trained (216) using a natural language processing (NLP)-based AI platform and expert validation within the NLP based AI platform, using, for example Boolean search strings or trained ‘classifiers’. The algorithms may detect emotion, cognitive tension, and momentum over time. The algorithms may reveal the emerging relationships between components of the variables and the DAGs.

The simulated outcomes, simulation models, predicted outcomes, DAGs, and algorithm outputs may be displayed (218) in a dashboard display of the simulation matrix to monitor emergence of complex risks or breakthrough inventions over time. The dashboard may highlight directional links to capture the non-linear behaviors of the system.

In some cases, the results may be outputted (220) as status messages and alerts against pre-defined thresholds, with hyperlinks to detailed descriptions contained in previous steps. For example, high momentum emerging risk may be coded red, while high impact breakthrough inventions may be coded green. Each outcome may be hyperlinked to detailed descriptions contained in previous steps.

In some cases, the simulation matrix is a library of nested macro matrix simulations, wherein each simulation is interconnected with other simulations to form a complex web of relationships. The library may include multiple tiers, including predicted outcomes libraries, extreme outcome libraries, and simulation model libraries, which are designed to capture specific types of data and insights.

Each simulation in the library is run independently, but they are all linked together so that any changes or results from one simulation can be passed on to another, allowing for the creation of a dynamic and interconnected system. The simulations are also designed to capture subtle patterns and trends, such as early warning signs of systemic instability or emerging risks.

In addition to the macro matrix simulations, multiple agents are provided, which are intelligent software agents that gather information from the simulations. The story agents are trained on the outputs of the simulations and use machine learning algorithms to identify patterns and anomalies in the data. The story agents are designed to feed off each other, recursively adding depth, detail, and unique insight to their analysis. This allows for the creation of a highly nuanced and detailed understanding of complex systems, which can be used to anticipate and prepare for systemic events.

The system may also include multiple early warning systems, which are trained on the outputs of the story agents. These early warning systems use machine learning algorithms to identify patterns and anomalies in the data and provide alerts and notifications when certain thresholds are reached. Overall, the system provides a highly advanced and dynamic framework for analyzing complex systems and identifying emerging risks and opportunities. The interconnectedness of the simulations and the story agents allows for the creation of a rich and detailed understanding of complex systems, which can be used to make informed decisions and anticipate systemic events.

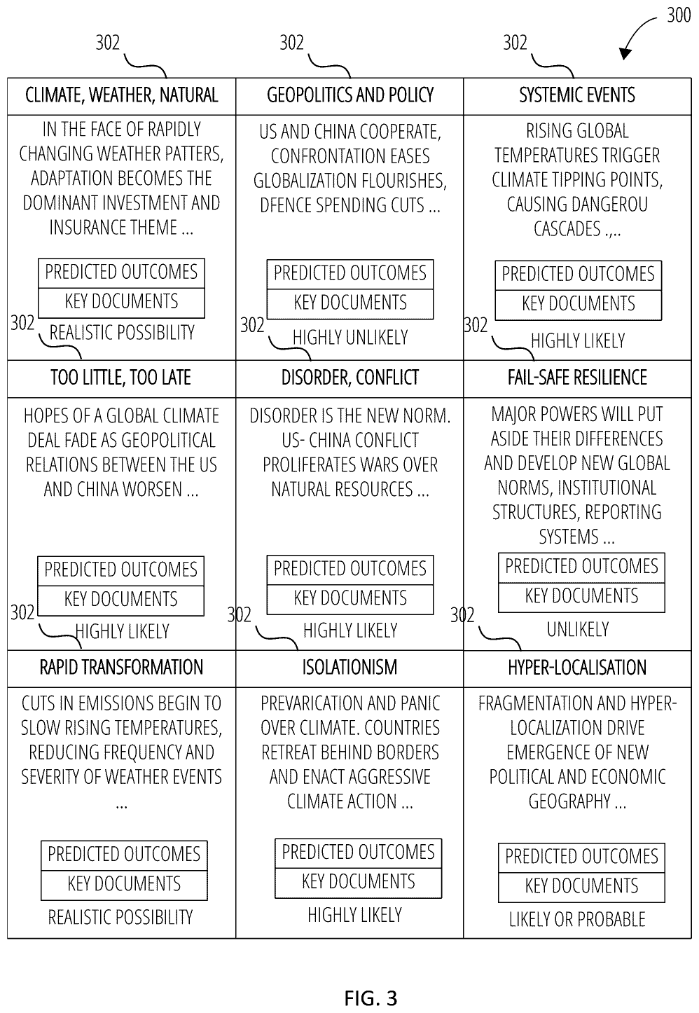

FIG. 3 illustrates an example dynamic simulation matrix dashboard.

The example dynamic simulation matrix dashboard 300 comprises a graphical user interface (GUI) that displays multiple simulations, emerging risks, and relationships between components within the system. The dynamic simulation matrix dashboard 300 includes a live dashboard that displays momentum, whether positive or negative, for each simulation. The direction of momentum may be indicated via color, such as red for negative momentum and green for positive momentum. This enables users to quickly identify emerging trends and potential catastrophic outcomes. Links may be provided between interactive cards 302 in the matrix to demonstrate best/worst-case simulations or combinations of emergent behaviors over time.

A live navigational framework may be embedded within the dynamic simulation matrix dashboard 300, allowing users to explore different simulations and relationships between components. The framework may include predicted outcomes that test possible policy interventions or the impact of breakthrough inventions on the system as a whole. Alerts may be provided to the emergence of simulation models with significant momentum between different predicted outcomes, which enables users to identify potential tipping points and cascades within the system.

The dynamic simulation matrix dashboard 300 may also display the output of algorithms that reveal changing future relationships between components, such as the significance of relationships between drought and water shortages. The dashboard provides situation awareness by highlighting the emergence of social, political, or economic shocks in anticipation of future events. Urgent policy actions may be triggered based on this information, such as early action to protect vulnerable coastal regions.

The dynamic simulation matrix dashboard 300 further provides real-time monitoring and prediction capabilities that identify potential risks and opportunities, and take proactive measures to mitigate or capitalize on emerging trends. To illustrate the functionality of the dynamic simulation matrix dashboard 300, consider the following simulation: war may be an endgame, as may famine or mass migration. These outcomes are imagined, possible, worst- or best-case outcomes over time, though they are not linear. War can lead to famine or energy crises, or famine can lead to war. The matrix would display multiple simulations between interactive cards 302, demonstrating the emergence of these outcomes and their relationships with other components within the system. The dynamic simulation matrix dashboard 300 would also provide simulated outcomes that test possible policy interventions, such as early action to protect vulnerable coastal regions. Furthermore, the dynamic simulation matrix dashboard 300 includes a feature that analyzes momentum, emotion, and sentiment associated with each term in the dynamic simulation matrix dashboard 300.

For example, the significance of the relationship between drought and water shortages may be codified, and the dynamic simulation matrix dashboard 300 provides situation awareness by highlighting the emergence of social, political, or economic shocks in anticipation of future events. Urgent policy actions can be triggered based on this information, such as early action to protect vulnerable coastal regions.

High-impact, high uncertainty system variables may become related, some causally, over time, such as climate crisis, geostrategic disorder, and inter-systemic failures, which may be the predicted outcomes of the system and resulting in emerging narratives. Within each variable, three scenario outcomes are illustrated, each made up of predicted outcomes over time and expressed as narrative models that act as agents within the system. The models are further encoded as search algorithms, which individually and together act as nested training scripts.

Every interactive card 302 within the dynamic simulation matrix dashboard may be ‘live’, updated and flexible. The simple narratives are underpinned and fed from real-time feed designed through the DAGs and trained algorithms. The dynamic simulation matrix dashboard 300 encodes and monitors multiple possible outcomes for each simulation variable, the relationships between the variable outcomes, such that early signs of, for example, ‘multilayered’conflict, divided US politics, and shared action by China, Russia and North Korea create an emerging cascade that can be the subject of momentum alerts and early warning.

Each variable outcome of the dynamic simulation matrix dashboard 300, such as drought, is expanded and specified as scenario outcome, simulation models, and predicted outcomes, narratives and directed acyclic graphs, in the form of search strategies and structured analysis, including detection and monitoring over time of sentiment and emotion. Similarly, each of the causal, simulated and emergent relationships between the variable outcomes may be expanded and specified in the same sequence. In practice, the sequence may be an encoded ‘cascade’—a series of causal or emergent relations over time. These may themselves be seen as sequenced narratives. To illustrate, the relationships between drought, crop failures, and food shortages may be encoded in the same form, such that the dynamics of the system are explicit and visible as they emerge over time. The outputs of the dynamic simulation matrix dashboard 300 may presented as alerts and status messages. The sequenced narratives form the basis of the library.

A generated story may be analyzed to determine when in a timeline relevant to the related stories the generated story occurs and insert the generated story into the related stories. In some embodiments, the generated story and related stories may be included in a prompt to a large language model such as “Generate a story which integrates [data] and [data],” where the first [data] comprises the generated story and the second [data] comprises one or more existing stories. Narratives may arrange a plurality of related stories into chronological order or may be arranged based on causal relationships. For example, a story describing the conflict between Israel and Hamas may precede retaliatory attacks by Houthi rebels against Israel and their allies. In other embodiments, a narrative may describe the impact of droughts, resulting from overuse of ground and surface water, a lack of precipitation, and the wildfires fueled by the dry conditions. In some embodiments, the related stories may comprise components of a story with a broader context. For example, a story may comprise election results, which may comprise a component in a broader story describing the likelihood of a country declaring war on its neighbor. Such stories with a narrower scope may, therefore, be completely or partially embedded within a larger story.

In some embodiments, these stories may be discrete stories and may be incorporated into larger narratives. In some embodiments, stories with narrower scopes may be included in multiple broader-scoped narratives. In some embodiments, stories and/or narratives may be nested within others representing varying levels of scope. Similarly, stories may be interconnected, and may therefore have parts or the entirety of a story included in multiple places within a single narrative. Similarly, narratives may share multiple similarities or common stories. Examples of common elements may include people, places, events, outcomes, etc. Stories may be arranged into a matrix which may be viewable by users of an event monitoring system 102 which may arrange stories including risk assessments, outcomes, status, momentum towards an outcome, etc. The stories may be arranged based on interventions, such that the stories describe possible or likely outcomes based on the type of intervention. Each box within the matrix is regularly updated with newly available information and simulation results. Multiple outcomes for each simulation variable are encoded and monitored, including the relationship between the variable outcomes, such as the early signs of a multilayered conflicts, divided United States politics, and shared action by China, Russia, and North Korea, creating an emerging cascade that can be the subject of momentum alerts and early warning.

In some embodiments, the matrix may comprise layers with increasingly narrow scope. For example, a broad scope may indicate alternative options for military intervention. A narrower scope may comprise a matrix of further options and/or outcomes based on the selected option. If military intervention is selected, multiple options for military interventions may be provided. Furthermore, if an option comprises establishing a beachhead, the narrower scope options and outcomes may include locations, success versus failure, risk and amount of losses, etc. Alternatively, each variable outcome of the matrix, such as drought, can be expanded as a scenario outcome, simulation model, and predicted outcomes, narratives, and directed acyclic graphs, algorithms, in the form of search strategies and structured analysis, including detection and monitoring over time of sentiment and emotion, and narratives including contributors and sources. Similarly, each of the causal, simulated, and emergent relationships between the variable outcomes can be expanded and specified in the same sequence. In some cases, the sequence is an encoded cascade or series of causal or emergent relationships over time. These may themselves be seen as sequenced narratives. For example, the relationships between drought, crop failures, and food shortages are encoded in the same form, such that the dynamics of the system are explicit and visible as they emerge over time. The outputs of the system may be presented as alerts and status messages in the form of a dashboard. The dashboard may highlight multi-directional links to capture the non-linear behaviors of the system.

For example, war, often seen as a worst-case outcome, may create food or energy crises. In some embodiments, narratives are represented as directed acyclic graphs that model causal relationships. They are designed to seek surprises, anomalies, and early signs of possible disruptive change. For example, the emotional and cognitive responses to emerging events within stories of individual protagonists, groups, and communities in relation to emerging futures, risks, and opportunities may be detected and monitored. The narratives and directed acyclic graphs encode both causal narratives, characterized by high levels of confidence, or narratives that may be generally accepted or culturally embedded and so have a political, economic, or social influence on decision-making and behavior. The same applies to narratives that describe imagined futures and are generally accepted, not as fact but as the basis of belief systems and worldviews. In some cases, sequences of events may be expressed as directed acyclic graphs, which describe the relationships between the events, or cascade of events, and between directed acyclic graphs, resulting in causal narratives.

The full narrative cascade for a potential or emerging outcome may show few results if the sequence has not yet crystallized; however, the component parts generate results, and their momentum forms the key to emergence within the early warning system. The full narrative will emerge only when a series of events and cascading system conditions are met. In some cases, the sequences, which may be represented by directed acyclic graphs, are defined as emerging narratives if and when each element in the sequence reaches a threshold value, or shows signs of reaching a threshold value, such as when droughts last longer than a predefined duration. For example, only a severe drought may create water shortages sufficient to trigger nuclear plant closures. The thresholds may be manually defined or detected through monitoring. In some embodiments, the combinatorial momentum of related direct acyclic graphs, or narratives, may act as early warnings. For example, multiple directed acyclic graphs, narratives, predicted outcomes, etc. may gain momentum which together may represent the crystallization or emergence of a narrative sequence, outcome, etc., whereas the same momentum for each directed acyclic graph, narrative, predicted outcome, etc. may be insufficient to establish the crystallization or emergence of a narrative sequence, outcome, etc.

Emergence within the system is automated and, given the scale of information, beyond the capacity of conventional human-only analysts. In some embodiments, emerging futures are framed within a specialist multivariable morphological space, such as in a simulation matrix of closed loop diagrams and are defined by the minimum number of independent variables necessary to describe a system. Created by domain specialists, they are the product of asking expansive, imaginative what-if questions. They are simulations modeled at all levels and represent a system mapping that captures key high-impact variables, latent relationships between them, and possible outcomes over time. Within the simulation matrix, multiple possible outcomes are mapped, creating hundreds and potentially thousands of simulations, through combinatorial linking between the variables and their particular outcomes. Possible outcomes are distinct from probable outcomes in that they are independent of the likelihood of occurring, such that an outcome with a low likelihood of occurring may not be probable but may still be possible.

The simulation matrix may comprise several variations based on live indicators showing emerging direction and future outcomes, such that the variables can be linked in time, causally related, or detected through novel relationships that emerge as both natural and human factors respond to changing system conditions. In the simulation matrix, each variable is encoded, and multiple possible outcomes that may emerge over time are described in rich narrative form. predicted outcomes are similarly encoded within the matrix as early indicators. In some cases, each variable or theme is encapsulated within a simulation matrix designed to map three or more possible outcomes over time. In another embodiment, the simulation matrix may take the form of a novel closed-loop diagram incorporating multiple possible outcomes for each node in the system, capturing the uncertainty of outcomes between variables over time, emerging causal relationships between them, and enabling live monitoring of emergence within the system. The outcomes are described as extreme simulations, both positive and negative, reflecting the inherent dynamic uncertainty of the real world.

The extreme outcomes are the product of specialist source selection and expert judgment and are described as radical, imaginative projections pushed forward over time. The simulation matrix variations are designed to reflect multiple possible imagined futures, their root causes, and pathways that may lead to them. The purpose of the simulation matrix is to assess the likelihood of inter-systemic failure and map the possible pathways and feedback loops that may emerge, forming the basis of a predictive modeling and navigational framework that includes alerts that indicate one simulation is emerging rather than another or that one narrative of an imagined future is more likely to crystallize and gain momentum than other competing future outcomes. In one embodiment, drought may be a variable that may be described as brief and localized, or at the other extreme, recurring in prolonged spells for years. It may be described simply or capture more complex relationships according to weather patterns, regional variations, and local infrastructural resilience. Drought as a variable has many outcomes that are emerging over time, each comprised of different outcomes and codified predicted outcomes that form the basis of the simulation matrix. The emergence of these outcomes is mapped, monitored, and evaluated at scale for inter-systemic risk, likely trigger events, and cascades that may, for example, develop as consequences of a space weapon attack on satellites that cuts global positioning system (GPS) services which may impact aviation, shipping, and financial market stability.

The imagined future outcomes are described in narrative form, a form of model-free exploration that may not rely on detailed evidence. One of the essential differences between existing systems and the event monitoring system 102 is the codifying of expansive, possible, and extreme imagined futures to avoid presentism and inherent status quo and confirmation biases. These narratives form the basis for monitoring catastrophic risk endgames or invention outcomes. For example, war may be an endgame, as may famine or mass migration. These outcomes are imagined, possible, worst- or best-case outcomes over time, though they are not linear. War can lead to famine or energy crises, or famine can lead to war. In some embodiments, the simulation matrix is a live dashboard that may be applied to any complex system characterized by multiple protagonists, high levels of system noise, and high volumes of data and information in media, social media, and academic literature that disguise underlying emerging realities. The dashboard, or simulation matrix, may display momentum, whether positive or negative. In some cases, the momentum direction may be indicated via color, such that red may represent momentum in the negative direction, and green may represent momentum in the positive direction.

The dashboard may contain links to narratives and/or underlying data sources. There may be links between boxes or cells in the simulation matrix which may represent relationships. Likewise, emergence may be indicated, as may severity of the possible outcome. In some embodiments, indications may be present which inform the user of the best-case simulation, and likewise the worst-case simulation. The dashboard may be updated dynamically as new information, simulation results, etc. become available and in response to potential policy decisions, whether hypothetical or actual. In this way, simulated outcomes within the simulation matrix may test possible policy interventions or the impact of breakthrough inventions. The dashboard provides situation awareness, highlighting the emergence of social, political, or economic shocks in anticipation of future events, such that urgent policy actions may be triggered, such as early action to protect vulnerable coastal regions.

The output from each earlier steps is displayed in the dynamic simulation matrix dashboard 300, such that the emergence of inter-systemic, complex risks or breakthrough inventions, or system emergence can be monitored over time. The dynamic simulation matrix dashboard 300 may highlight multi-directional links to capture the non-linear behaviors of the system. To illustrate, war, often seen as a worst-case outcome, may create food or energy crises. The output codifies possible cascades and narrative structures that combine to point to one simulation pathway or another, alerting emergence of one simulation or another over time according to momentum and signs of cognitive tension and emerging conviction.

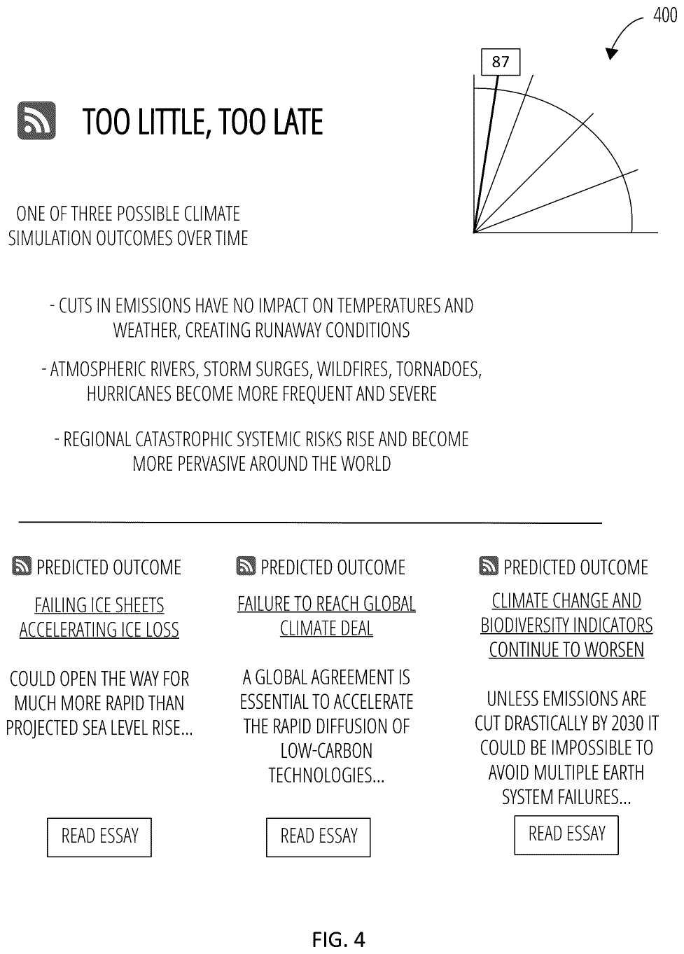

FIG. 4 illustrates an example expanded view of one of the interactive cards.

In some cases, selecting the interactive card 302 may lead to an expanded view 400 of the interactive card 302. An example expanded view may include narrative models that are associated with simulation models that are designed to search large-scale sources, search curated, domain-specific sources, and monitor momentum and salience over time.

The predicted outcomes 204 may be further describe in future-oriented narratives, defined by uncertainty, and may follow structure: context or theme; rising tension and uncertainty; climactic event; convergence to new dominant story; ending. The future-oriented narratives may be created based on the relationships between the variables.

The expanded view 400 of selecting one or more interactive cards 302 may reveals a complex web of relationships between variables, comprising directed acyclic graphs (DAGs) that model causal narratives and predicted outcomes. Each interactive card 302 may represent a specific variable or simulation, encoded as a unique combination of a simulation model and predicted outcomes. Upon expansion, the interactive card 302 may reveal multiple sub-cards or links, each representing a distinct perspective on the variable's relationships with others. For instance, when a user selects the “Too Little Too Late” card, the expanded view may display features that represent a DAG structure that illustrates the causal connections between climate change, economic instability, water scarcity, and global conflict. The DAGs may define the intricate web of cause-and-effect relationships, where each node represents a variable or simulation, and the directed edges represent the direction of causality. Upon further expansion, multiple essays may be displayed as clickable links, providing detailed explanations of specific components within the expanded view.

For example, when the user clicks on the “Failing Ice Sheets Accelerating Ice Loss” sub-card associated with the “Too Little Too Late” card, a linked essay provides in-depth analysis of the change in water levels caused by climate change, including case studies and policy recommendations. Similarly, clicking on the “Failure to Reach Global Climate Deal” sub-card reveals an essay that delves into the impacts of lack of global cooperation may have on climate including data visualizations and expert opinions.

As users navigate the expanded view, they can access additional resources and information through links to relevant essays, research papers, and other supporting materials. These supplementary materials provide a wealth of detailed information on specific topics, including technical data, case studies, and expert opinions. By integrating these resources into the expanded view, users can gain a deeper understanding of the subject matter and develop more effective strategies for addressing complex problems. The interactive nature of the expanded view also enables users to save and revisit specific configurations of nodes and edges, allowing them to track changes over time and identify patterns that emerge from repeated interactions. This feature facilitates iterative analysis and decision-making, as users can refine their understanding of complex systems by repeatedly exploring different simulations and variables.

The dynamic simulation matrix dashboard 300 may be further utilize a Closed Loop Diagram (CLD) to define factors in terms of uncertain variables. Simulations and exploration of extreme possible outcomes over time are encoded as high-level models, which provide situation awareness by highlighting the emergence of social, political, or economic shocks in anticipation of future events. Each variable may be encoded and multiple possible outcomes that may emerge over time are defined. These outcomes are represented as directed acyclic graphs (DAGs), which define causal narratives based on specialist judgment and source selection. The DAGs encode scientific discovery and breakthrough invention by defining relationships between variables. The DAGs are then algorithmically tested using natural language processing (NLP) based AI platforms, which detect emotion, cognitive tension, momentum over time, and reveal emerging relationships between components of the variables.

For example, the significance of the relationships between drought and water shortages may be identified through the detection of momentum, emotion, cognitive tension, uncertainty, and sentiment. Each variable or part of a variable can be delivered from independent selected sources, such as patents, patent intelligence, or expert judgments, via an API link. These specially selected sources are licensed in the form of non-fungible tokens (NFTs) to guarantee copyright, authenticity, and provenance. The system also includes an emergence stage where each step is encoded and tested by source selection and specialist experts to measure momentum over time, analyze sentiment and emotion over time, and detect feedback loops with simulation matrix/CLD.

Simulations in this stage are hypothetical or imagined futures. The dynamic simulation matrix dashboard 300 may then further provide output in the form of status messages and alerts against pre-defined thresholds. For example, high impact breakthrough inventions may be coded green, while emerging risks may be coded red. Each outcome may be hyperlinked to detailed descriptions, such as the essays. The dynamic simulation matrix dashboard 300 showcases the emergence of inter-systemic, complex risks or breakthrough inventions in real-time, and further highlights multi-directional links to capture non-linear behaviors of the system.

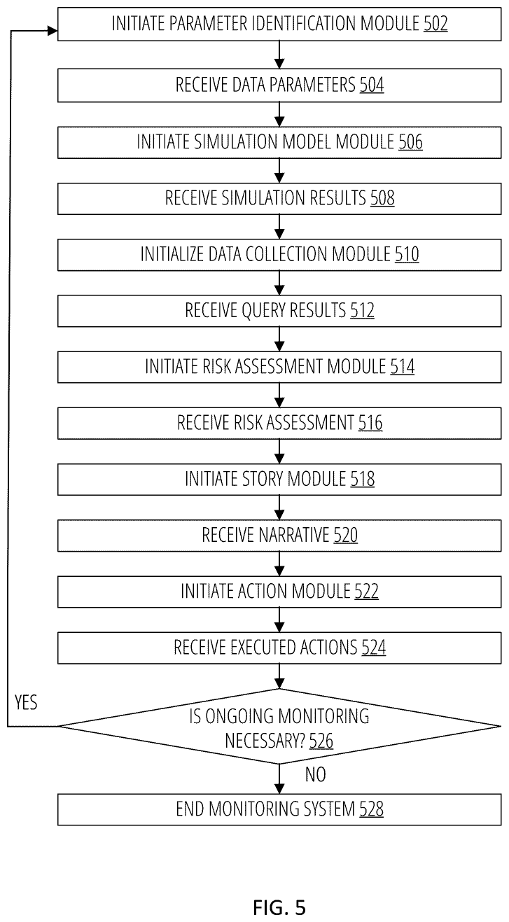

FIG. 5 illustrates a control module.

The process begins with initiating at step 502, the parameter identification module 122. The parameter identification module 122 receives structured data, such as an insurance contract, and extracts the received structured data. In some embodiments, the received data may be unstructured. In such embodiments, the data extraction may comprise providing structure to the data, such as by utilizing natural language processing or object recognition to convert text, audio, or images into structured data which may be assigned to fields in a database. One or more parameters are identified from the extracted data and the identified parameters are saved to the parameter database 110.

Receiving at step 504, one or more data parameters from the parameter identification module 122. Examples of parameters may comprise the start and end date of an insurance contract, a risk event, a simulated possible future event, and the date of an event from a news article that may be relevant to the insurance contract, risk event, or simulated possible future event.

Initiating at step 506, the simulation model module 124. The simulation model module 124 queries the parameter database 110 for parameters that may be related to a search query or received structured data, such as an insurance contract, and one or more parameters are selected. The simulation model database 112 is queried for simulation models related to the selected parameters, and a simulation model is selected. The simulation model performs simulations to determine one or more possible outcomes, and the simulation results are received from the simulation model. These may be approximations that account for proximity to narrative model or momentum towards an ending, or story. One or more predicted outcomes may be identified from the simulation results. predicted outcomes are events or outcomes with a low likelihood of occurring, however, which may have a significant impact if or when such events or outcomes occur. The simulation results are saved to the simulation model database 112. If there are more simulation models that have yet to perform simulations, another simulation model is selected. If all simulation models have performed simulations and there are more parameters for which simulation models have not been selected and simulations performed, then select another parameter or combination of parameters.

Receiving at step 508, simulation results from the simulation model module 124. The simulation results may comprise one or more identified predicted outcomes or simulation model outputs. In some cases, a received predicted outcome comprises “Houthi rebel increased violence in the Red Sea.” Initializing at step 510, the data collection module 126. The data collection module 126 queries the simulation model database 112 for simulation results which may comprise one or more predicted outcomes. Simulation results, such as a predicted outcome, are selected, and a connection is established to a large language model network. A large language model network may comprise a third-party service such as OpenAI's ChatGPT, Microsoft's Bing Chat or Copilot, Google's Bard or Gemini, Meta's Llama, etc. A large language model may also refer to a natural language processing service such as PrimerAI, which may utilize methods other than large language models and generative AI, such as traditional natural language processing methods that convert natural language text, audio, or visual input into data which may be used in computational processing by one or more computing systems. Such services may be accessed via an application programming interface. In some embodiments, the large language model may be part of an event monitoring system 102.

A search query is generated, which may utilize a prompt database 114, and the generated search query is submitted to either a large language model, search engine, or a database. The format of the search query may vary based on the platform to which the query is to be submitted. For example, a search query submitted to a large language model may comprise a natural language prompt with instructions indicating the type of response to be received. A search query to a search engine may comprise keywords and other relevant parameters. A search request for a database may comprise a structured query language query. The received query results are compared to the simulation model results and matching results are saved to the simulation model database 112.

Receiving at step 512, query results from the data collection module 126. Query results may comprise additional data relating to simulation model results, which may include a predicted outcome. The query results may comprise data from a plurality of sources. Examples of the query results may include news articles, intelligence reports, research papers, etc. Initiating at step 514, the risk assessment module 128. The risk assessment module 128 queries the simulation model database 112 for simulation results such as predicted outcomes. A predicted outcome is selected, and the likelihood of realization of the selected predicted outcome event or outcome is predicted. The impact of the realization of the selected predicted outcome event or outcome is also predicted. A risk score is then determined, which may comprise a plurality of discrete values representing different types of risk or may comprise an aggregate score. The risk score is saved to the simulation model database 112 associated with the selected predicted outcome. If more predicted outcomes are to be assessed, another predicted outcome is selected. Receiving at step 516, a risk assessment from the risk assessment module 128. The risk assessment may comprise an aggregate score or a plurality of discrete values representing different elements of risk.

Initiating at step 518, the story module 130. The story module 130 queries the simulation model database 112 and the story database 116. A risk assessment associated with one or more predicted outcomes is selected, and a connection is established to a large language model network. A large language model network may comprise a third-party service such as OpenAI's ChatGPT, Microsoft's Bing Chat or Copilot, Google's Bard or Gemini, Meta's Llama, etc. A large language model may also refer to a natural language processing service such as PrimerAI, which may utilize methods other than large language models and generative AI, such as traditional natural language processing methods that convert natural language text, audio, or visual input into data which may be used in computational processing by one or more computing systems. Such services may be accessed via an application programming interface. In some embodiments, the large language model may be part of an event monitoring system 102.

A prompt is generated, which may utilize a prompt database, 114 which is submitted to the large language model. A story is received from the large language model in response to the submitted prompt. Related stories are identified from the data received from the story database 116. Related stories may share keywords, parameters, or other context. In some embodiments, a large language model may be used to identify related stories. The related stories are arranged into a narrative, such as by ordering the stories chronologically. In some embodiments, the individual related stories may be submitted to a large language model as part of a prompt with instructions to summarize the provided stories as a narrative. The narrative is saved to the story database 116. If there are more risk assessments, another risk assessment is selected.

Receiving at step 520, one or more narratives generated by the story module 130. Each narrative comprises at least one story, and which may additionally comprise summarized data from a plurality of related stories. Initiating at step 522, the action module 132. The action module 132 queries the story database 116 and the action database 118. A story is selected from the story database 116 which may comprise a narrative composition of a plurality of independently generated stories, and an action is selected from the action database 118. The action additionally comprises action criteria, which are trigger conditions that must be satisfied prior to the action being executed. If the trigger condition has been satisfied based on data described or associated with the selected story, then execute the action. The executed action may be saved to the action database 118. If there are more actions to be assessed, select another action. If there are more stories to be assessed, select another story.

Receiving at step 524, one or more executed actions from the action database 118. In some embodiments, one or more actions may have been executed. In other embodiments, no actions may have been executed. Determining at step 526, whether ongoing monitoring of a risk, emerging event, or development is necessary. The determination of whether ongoing monitoring of risk may be dependent on an algorithm that calculates whether the risk associated with submitted data is above a threshold level that may include, for example, momentum, proximity to the narrative model, and relationship to the story ending. For example, if there is a likelihood of an event that may result in more than one fatality, 5 casualties, one million dollars in losses, and greater than 10% likelihood of such outcomes occurring. In another embodiment, ongoing monitoring of risk is no longer necessary if a parameter, such as a time period of interest, has passed. In some cases, the date is Apr. 18, 2024, which is after Apr. 17, 2024, the ending date of an insurance contract term. Therefore, ongoing monitoring is no longer necessary. In alternate embodiments, whether ongoing monitoring is necessary may be dependent upon a user or operator of an event monitoring system 102. If ongoing monitoring is necessary, return to step 502, and initiate the parameter identification module 122. Ending at step 528, the event monitoring system 102 session.

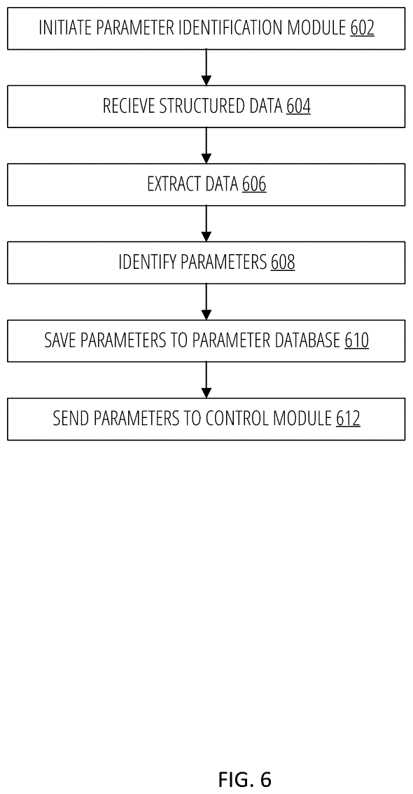

FIG. 6 illustrates a parameter identification module.

FIG. 6 illustrates the parameter identification module 122. A method may begin with initiating at step 602, the parameter identification module 122 by the control module 120. The process may continue with receiving at step 604, structured data from a user, network, or database. For example, the structured data may comprise a query or uploaded contract document from a user. In another embodiment, the structured data may comprise a query from a third-party network 136 or a third-party database 138. Structured data may comprise insurance contracts, pre-defined military or security events, intelligence estimates, expert simulations of future developments, queries from a policymaker or other interested party, a news article, etc. In some embodiments, the received data may not be structured, such as image, audio, or video data.

The data may be received directly from the user of an event monitoring system or may be received via a third-party network 136, web scraping, etc. In some embodiments, the structured data may comprise simulation model simulation results, which may be stored in the simulation model database 112. Some embodiments may comprise one or more imagined futures, or interconnected futures, such as future technologies. Examples include the development of AGI, quantum computers, impacts of climate change, including food and water insecurity, or the United States dollar losing dominance in international financial systems.

The method may further include extracting at step 606, data from the received structured data. The extracted data may comprise matching data fields from a digital form with fields in a database. Alternatively, the extracted data may comprise data acquired via natural language processing of imaged text, such as from a scanned document, or from transcription of audio, such as from a live voice conversation or a recording. In some cases, extracting the data may comprise pairing data from the structured data to a field in the parameter database 110 or, alternatively, a third-party database 138. In another embodiment, extracting data may comprise transcribing audio data into text, translating a foreign language into a native language, such as French into English, or using machine vision on an image or sequence of images to identify relevant information such as objects, people, locations, etc.

The method may further include identifying at step 608, parameters from the extracted data. Parameters may comprise data that is relevant to the received data, specifically data that may help predict future events related to the received data. Examples of parameters may comprise the start and end date of an insurance contract and the date of an event from a news article that may be relevant to the insurance contract. For example, if Houthi rebels attack shipping lanes through the Red Sea on Apr. 10, 2024, and an insurance company has issued a policy for a shipping vessel traversing the Red Sea between Apr. 8, 2024, and Apr. 17, 2024, with a variable rate, the insurance company may increase the rate based upon the increased volatility and risk in the region. Alternatively, the insurance company may revoke the policy or advise the owners of the insured vessel to avoid the region or trigger new exclusions, claim limits, or terms, etc. Parameters may relate to queries submitted by an interested party, such as a policy maker or researcher. In some embodiments, some queries and/or parameters may be continuously monitored, such as drought, famine, wildfires, war, etc. The method may further include saving at step 610, the identified parameters to the parameter database 110. The method may further include sending at step 612, the identified parameters to the control module 120.

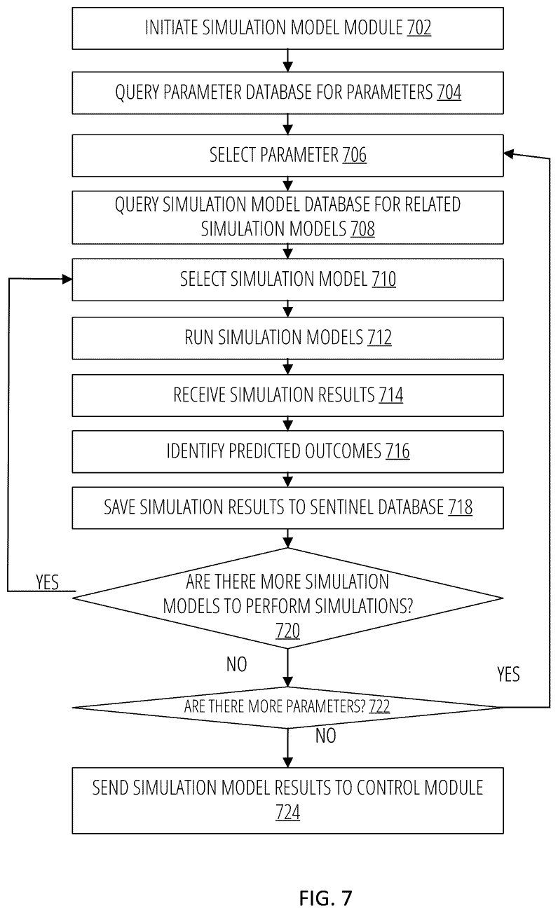

FIG. 7 illustrates a simulation model module 124.

The method may begin with initiating at step 702, the simulation model module 124, by the control module 120. The method may further include querying at step 704, the parameter database 110. The data from the parameter database may include parameters related to received data, such as from a query. For example, the parameters may comprise data from one or more insurance contracts related to shipping vessels traversing the Red Sea and one or more news articles relating to increasing violence in the Red Sea. In another example, the parameters may comprise data relating to an imagined future, such as the development of quantum computers.

The method may further include selecting at step 706, one or more parameters from the data received from the parameter database 110. In some cases, selecting the parameters of Apr. 8, 2024, through Apr. 17, 2024, and the Red Sea. In other embodiments, the parameters selected may comprise “drought” and “wildfires.” In another embodiment, the parameters may comprise “war” and “famine.”

The method may further include querying at step 708, the simulation model database 112. The simulation model database 112 stores simulation models, which in some embodiments are pure simulations unaffected by external data and about which there is initially no evidence or historical precedent. simulation models may comprise metadata or story agents, identifying relevance to data, topics, events, etc. In some embodiments, this metadata may comprise data related to the simulation model's initial state, such as the location, time, relevant people, etc. In other embodiments, the metadata may comprise data related to possible outcomes identified by the simulation model. A plurality of simulation models may exist simultaneously. Each simulation model may comprise at least one parameter or variable making the simulation model unique. In alternate embodiments, some simulation models may comprise identical initial criteria but may be comprised of variable parameters such that different outcomes may be achieved based on variable probabilities or, in security applications, references to the Admiralty Code that assesses information by source and by references to source track records.

In some embodiments, the simulation model database 112 may store the results of previous simulations performed by the simulation models. Some simulation models may be representative of causal relationships such that their starting conditions are the ending state or reflect outcomes of other simulation models. In some embodiments, simulation models may be related, such as representing differing outcomes of the same simulation, such that one or more variables are changed, or each represents a probable outcome of one or more diverging events or simulations, such as the results of an election, or a policy decision. In such embodiments, the existing simulation models are not changed. Instead, new simulation models may be generated with consideration to the newly identified outcomes, probable outcomes, etc. Selecting at step 710, a simulation model that matches at least one selected parameter. In some cases, a simulation model may comprise a simulation spanning the period of Apr. 8, 2024, through Apr. 17, 2024, and relating to the Red Sea. In some embodiments, the simulation model may be more specific, such as directly relating to events that may relate to shipping vessels.

In another embodiment, a simulation model may comprise drought conditions in Southeast Asia. In another embodiment, a simulation model may comprise a dam breach in China. simulation models are based on forward-looking data and may represent competing futures, contests such as elections, worldviews, intelligence estimates, and representations of information, which may include misinformation, whether spread intentionally or otherwise. The simulation models may represent reactions to events and may consider responses, such as those based upon logic, reason, or emotions, of individuals, groups, governments, etc. The simulation models may simulate narrow simulations, such as representing the direct results of a single decision, or may comprise complex simulations that may be intertwined and impacted by a plurality of more narrowly scoped simulation models. For example, simulating hazards for ships traversing the Red Sea may comprise a plurality of simulation models considering threats represented by different countries, groups, etc., or possible events, such as acts of aggression against or by Israel. simulation models may, therefore, be nested within other simulation models or may be interlinked based on causal relationships. In another embodiment, selecting a simulation model focused on the consequences of the continued development of quantum computers.

Running at step 712, simulations by the selected simulation model. The simulations represent a possible sequence of events that may predict future events. The simulations are performed based on a set of initial parameters. The parameters may comprise a level of variability, allowing varying outcomes. In some embodiments, the simulations are not affected by external parameters. For example, the simulation model does not undergo additional training utilizing external data. In some embodiments, multiple simulations are performed and may be aggregated to determine a probabilistic representation of possible outcomes. In some cases, the selected simulation model performs a simulation of shipping activity in the Red Sea, including the time period between Apr. 8, 2024, and Apr. 17, 2024. For example, the simulations may include disruptions caused by high traffic or restricted shipping channels due to blockades, or the threat of attacks from militant groups such as Houthi rebels. In another embodiment, a simulation model simulates the development of violence in the Middle East, including the time period between Apr. 8, 2024, and Apr. 17, 2024, which may include increased hostilities between Israel and Arab nations such as Yemen, Iran, and Jordan. In other embodiments, the simulation model may simulate drought conditions in Southeast Asia. For example, the simulations may comprise the development of drought conditions in Vietnam and consequential developments such as a lack of drinking water, wildfires, political instability, etc. In another embodiment, a simulation model may simulate a dam breach in China. For example, the simulation model may simulate a failure of the Three Gorges Dam. The simulation may include second, third and n-order consequences that includes, for example, damage from flooding, political and economic consequences, casualties, etc. In some cases, the simulations may comprise the threat to encryption represented by the development of quantum computing.

Receiving at step 714, simulation results from the simulation model. The simulation results may comprise one or more possible outcomes. The possible outcomes may additionally comprise a probability of the outcome. In some cases, the results for a simulation comprising shipping activity in the Red Sea, including the time period between Apr. 8, 2024, and Apr. 17, 2024, comprising 32% of all ships traversing the Red Sea during the time period of interest receiving damage from increased hostilities in the region. In another embodiment, a simulation of the development of violence in the Middle East, including the time period between Apr. 8, 2024, and Apr. 17, 2024, comprising increased attacks by Iran and Houthi rebels with collateral damage to shipping traffic in the region. In another embodiment, the results of a simulation of drought conditions in Southeast Asia may indicate political instability resulting from a shortage of drinking water. In another embodiment, the results of a simulation of the failure of the Three Gorges Dam indicate a low probability of significant casualties from flooding. In some cases, the simulation results include the development of quantum computers compromising the security of encryption used for financial transactions.

Identifying at step 716, one or more new predicted outcomes. A predicted outcome is an event or outcome in one case with a low probability of occurring. predicted outcomes may exhibit one or more characteristics, such as degrees of contestation, competing indicators of possible endings, cognitive tension amongst protagonists, or high levels of uncertainty and complexity. predicted outcomes may be identified through source selection, novel language, or new categories, both in macro-relations and in breakthrough inventions. New language, words, themes, or concepts may be detected by large-scale scanning, then codified as predicted outcomes and monitored. New language is a defining feature of emergence. New words may be selected from public sources, such as the Oxford English Dictionary, from scientific discoveries, commissioned from domain specialists, or from novel cultural constructs. predicted outcomes may comprise the defining features of an invention and the delivery of predictive value. In some embodiments, a predicted outcome may be determined by a probability below a threshold value, such as 1%. In other embodiments, a predicted outcome may be the lowest probability outcome or the five outcomes with the lowest probabilities of occurring resulting from simulation model simulations. In some cases, a predicted outcome may be the likelihood of a ship traversing the Red Sea between Apr. 8, 2024, and Apr. 17, 2024, being struck by a weapon fired by Houthi rebels. In another embodiment, a predicted outcome may comprise a low probability of political instability leading to civil war in Vietnam resulting from droughts.

predicted outcomes may additionally represent trigger conditions as opposed to events. For example, a correlation may be identified between initial conditions for a plurality of simulation models, which result in the same outcome. For example, a low probability of the failure of the Three Gorges Dam resulting in significant casualties due to flooding may be the result of sabotage. These outcomes may be desirable or undesirable. For example, there may be a low likelihood of successful peace talks between Israel and Arab nations, resulting in the elimination of hostile organizations and stability in the Middle East. In some cases, a predicted outcome may comprise the development of quantum computers with the potential for widespread distribution in commercial and consumer markets. In some embodiments, simulation model and simulation results may not include any predicted outcomes.

Saving at step 718, the simulation results to the simulation model database 112. The simulation results may comprise one or more identified predicted outcomes. Determining at decision block 720, whether there are more simulation models for which simulations have not been performed. If there are more simulation models, return to step 706, and select a simulation model. In some cases, another simulation model related to the Red Sea and the time period between Apr. 8, 2024, and Apr. 7, 2024, comprises US Navy operations in the Red Sea, therefore return to step 706 and select the next simulation model. Determining at step 722, whether there are more parameters for which simulation model simulations have not been performed. In some cases, another parameter exists comprising the activity of Houthi rebels between Apr. 8, 2024, and Apr. 17, 2024 and the other parameter is selected in step 706. Sending at step 724, the simulation results to the control module 120. In some embodiments, the simulation results may comprise at least one predicted outcome.

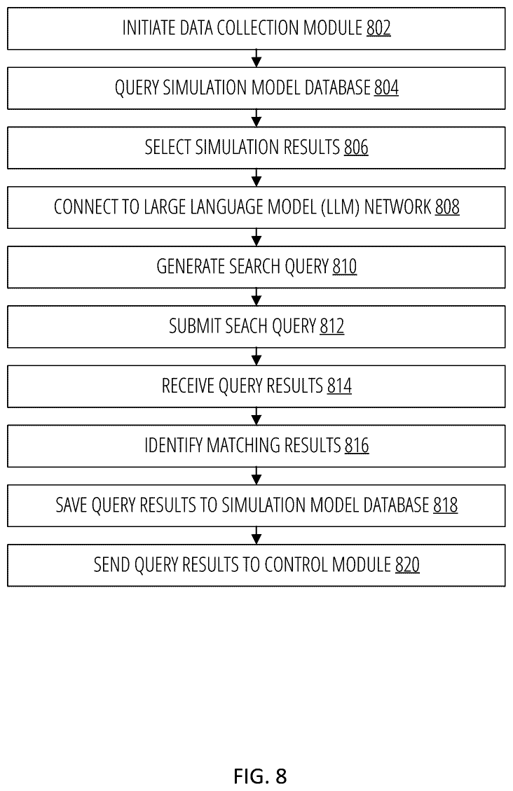

FIG. 8 illustrates a data collection module.

FIG. 8 illustrates the data collection module 126. The method may begin with initiating at step 802, the data collection module 126 by the control module 120. The method may further include querying at step 804, the simulation model database 112. The simulation model database 112 stores simulation models, which in some cases are pure simulations unaffected by external data. The simulation model database 112 may additionally store results of simulations that may include one or more predicted outcomes. Selecting at step 806, simulation results related to received data, such as from a contract or a query. In some embodiments, the selected simulation results may comprise one or more predicted outcomes. For example, the simulation results may comprise “Houthi rebel increased violence in the Red Sea.”

The method may further include connecting at step 808, to a large language model network. In some embodiments, the connection may comprise the submission of hypertext transfer protocol (HTTP) requests via an application programming interface (API). A large language model network may comprise an open-source or proprietary large language model. In some embodiments, a large language model network may be hosted by a third-party network 136. Large language models may comprise monomodal or multimodal models. A monomodal model receives prompts and returns responses using the same data type, such as text. A multimodal model can receive and/or return responses using different data types such as text, speech, or other audio, images, video, etc. A large language model may also refer to a natural language processing service such as PrimerAI, which may utilize methods other than large language models and generative AI, such as traditional natural language processing methods that convert natural language text, audio, or visual input into data which may be used in computational processing by one or more computing systems, or ‘spatial web’ or ‘active inference’ models.

The method may further include generating at step 810, a search query based upon the selected simulation results. Generating a search query may comprise generating a prompt from the prompt database 114. The prompt database 114 may store previously generated prompts which may comprise a data component and a request component. The data component is structured to provide context regarding data that is provided with the request, and the request component describes the type of response to be returned by the large language model. In some embodiments, the large language model may be fine-tuned for a specific purpose. Fine-tuning comprises a process of further training a pre-trained generative transformer with task-specific data, including a correct response, also known as a label. In some embodiments, prompts may be generated for different large language models depending on the type of data and/or request being generated. In some embodiments, the prompts in a prompt database 114 may have been generated by a large language model. Some embodiments may include a [data] component of the prompt, which is a placeholder for data, which may be found in a database, or from simulation results from one or more simulation models including one or more predicted outcomes. In some embodiments, the search query may comprise an algorithmic composition of search terms, such as one or more predicted outcomes, data, and context information related to the simulation results.

In some cases, the information component may comprise, “Considering the predicted outcome: [data],” and the request component may comprise “Provide a list of news articles relating to the predicted outcome.” In the example, [data] is one or more selected simulation results comprising one or more predicted outcomes. In some embodiments, the search query may be based on one or more parameters, such as setting, places, people, objects, events, outcomes, etc. The search query may search for evidence supporting an outcome, or which may establish proximity and/or momentum towards the outcome. In some embodiments, the search queries may comprise a logical syntax such as IS IT NECESSARY TO INCLUDE THESE FORWARD LOOKING OR ‘FUTURES’ TERMS? WE HAVE AND ARE BUILDING ON A LEXICON OF SUCH TERMS. MIGHT THESE BE BETTER RETAINED AS TRADE SECRETS? “Drought AND (century OR decade OR era OR tomorrow OR year OR future OR “long-term” or generation or “future generations”) AND (coming OR emerging OR constant OR continual OR continuous OR ongoing OR “on-going” OR onward OR perpetual OR “prospect of” OR horizon)” relating to the consequences of a drought which may potentially be emerging, ongoing, long-lasting, etc. Submitting at step 812, a search query that may comprise submitting the generated prompt to the large language model network. In some cases, the prompt may be submitted as an HTTP request via an API. In other embodiments, the large language model may be integrated into an event monitoring system 102, and therefore, a prompt may be submitted directly.

A prompt may comprise multiple components, including a data component and a request component. A prompt may additionally comprise a system prompt, which may provide further context for the type of response to be returned. For example, a system prompt may instruct the large language model to provide a text response from the perspective of a political science researcher, risk analyst, journalist, etc., seeking additional information related to the provided predicted outcome data. The prompt may be submitted as text or speech. In some embodiments, the data component may additionally comprise data tables, charts, figures, etc. In some embodiments, a prompt may further include a request component describing the information to be returned by the large language model. In some embodiments, the search query may be submitted to a search engine or as a database query which may be in the form of structured query language (SQL).

In such embodiments, the query submitted may comprise the response received from submitting the generated search query to a large language model. For example, a prompt is submitted where the information component comprises “Considering the predicted outcome: [data],” the request component comprises “Create a search query to be submitted to a search engine to find relevant references,” and the [data] represents the predicted outcome, “Houthi rebel increased violence in the Red Sea.” The large language model response may comprise ‘“Houthi rebels” “Red Sea” increased violence recent news’. The generated query may then be submitted to a search engine such as Google, Bing, Factiva, or Lexis Nexis, etc. In some embodiments, the generated query may comprise an SQL query which may be submitted to an SQL database.

The method may further include receiving at step 814, query results. In some embodiments, the query results may comprise a response from the large language model. The response may be in the form of natural speech or text or may include other modes such as images, data, etc. In some embodiments, the response may be received in a series of iterative prompt and response cycles such that the large language model may generate an additional prompt as part of the response to receive additional information. In some embodiments, the query results may comprise a list of references and relevant data provided by a search engine or via results from an SQL query.

For example, a prompt is submitted where the information component comprises “Considering the predicted outcome: [data],” the request component comprises “Provide a list of news articles relating to the predicted outcome,” and the [data] represents the predicted outcome, “Houthi rebel increased violence in the Red Sea.” The response may comprise a list of links to news articles relating to Houthi rebel violence in the Red Sea. In some embodiments, the list may include summaries of the articles, the full text of the articles, or data extracted from the articles. If the same prompt were submitted with the [data] instead referencing the predicted outcome, “wildfires from drought”, the list of results may include articles about wildfires in Australia, the western United States, and Canada. The received data may comprise evidence related to a possible outcome, and may represent data which may establish the proximity to the outcome, or the immediate likelihood of the outcome occurring, and may similarly support determination of momentum toward the likelihood, such as whether the rate of change of the proximity to the outcome is increasing. In some embodiments, the query results may comprise misinformation and/or stories comprising myth, legend, etc.

Further simulations may determine the authenticity of the data and may similarly simulate the impact of the information regardless of its validity. For example, misinformation may lead individuals, groups, governments, etc., to action despite being false, and therefore may have an impact as significant as if the information were true. In some embodiments, the received data may comprise language in scientific and patent literature, where novelty may be defined by new patent categories, language, or storylines and has predictive value as inventions are translated into innovation and rolled out in commercial endeavors. The results may be discovered and/or analyzed using third-party algorithms that demonstrate that in fast-moving areas, including artificial intelligence, predictive models have value in setting research agendas and focusing investment in breakthrough invention. In some embodiments, simulation models may utilize scientific and patent literature to perform simulations relating to the development, commercialization, and short-, medium-, and long-term consequences of technological innovations.

In another embodiment, patent filings inherently have predictive value to show the future shape of industry sectors, and so on long before commercialization, and may be analyzed using algorithms that rate the likelihood of commercial value. The received data may be used to further imagine possible future problems and invent solutions. By applying this approach strategically, projecting forward grand challenges in the context of future simulations, the challenges are codified and embedded in purpose-built search algorithms. In this application, the primary sources are patent databases, the public web, and scientific literature. Since breakthroughs are critical to policymakers and corporate strategists alike, early warning and predictive models based on estimates of time to market, commercialization, and proof of concept prototypes all have value.

The method may further include identifying at step 816, query results matching simulation model results. In some cases, the query results match one or more selected predicted outcomes. The query results may comprise one or more large language model responses, search engine query responses, or SQL query responses. Matching results may comprise determining whether select keywords are present in the returned response or each reference if a list of references is provided. For example, if the simulation model results comprise a predicted outcome comprising Houthi rebel violence in the Red Sea, then the results may match if they reference at least two keywords from the list of “Houthi,” “Red Sea,” and “violence.”

The method may further include saving at step 818, the query results to the simulation model database 112. In some cases, only matching results will be saved to the simulation model database 112. In some embodiments, the received query results may be subjected to a process of data validation, such as corroborating the data received with data known to be true, or by assessing the validity of the data based upon the data's source. In such embodiments, data determined to be inaccurate, false, or which may represent misinformation or disinformation may be omitted or may alternatively be assigned a trustworthiness or reliability score. In some embodiments, query results may be automatically screened for accuracy and trustworthiness. In alternate embodiments, query results may be reviewed by experts. Matching the query results to the simulation model results may comprise a selection of data sources.

Similarly, algorithm design, source optimization, and predictive performance are interdependent, therefore search strategies and data sources may be updated based upon the results of each query. Data sources may be tailored to specific needs and adapted to changing requirements, as well as the addition of new, third-party sources. Such customization and refinements may comprise training and evaluating predictive value and performance over time, in order to optimize the match between data sources and algorithm design. The momentum behind predicted outcomes, for example, is a source of a feedback loop between algorithm and source performance and early detection of emerging risk. Sending at step 820, the query results to the control module 120.

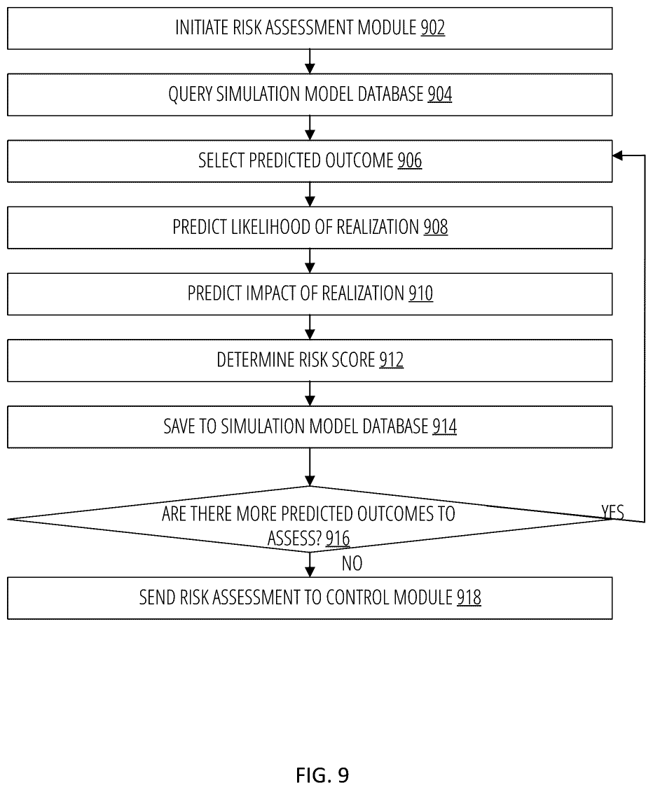

FIG. 9 illustrates a risk assessment module.

FIG. 9 illustrates the risk assessment module 128. The process begins with initiating at step 902, the risk assessment module 128 by the control module 120. Querying at step 904, the simulation model database 112. The simulation model database 112 stores simulation models, which in some cases are pure simulations unaffected by external data. The simulation model database 112 may additionally store results of simulations that may include one or more predicted outcomes and data collected by the data collection module 126.

Selecting at step 906, one or more predicted outcomes. A predicted outcome is an event or outcome with a low probability of occurring. In some embodiments, a predicted outcome may be determined by a probability below a threshold value, such as 1%. In other embodiments, a predicted outcome may be the lowest probability outcome or the five outcomes with the lowest probabilities of occurring resulting from simulation model simulations. In some cases, selecting the predicted outcome of “Houthi rebel increased violence in the Red Sea.” In another embodiment, the predicted outcome “wildfires from drought” is selected.

In some embodiments, multiple predicted outcomes may be assessed together, such as if they were identified from the same simulation, or if they are identified as having a causal relationship. In some embodiments, multiple predicted outcomes may be assessed together from multiple simulations if, for example, the predicted outcomes were the results of variable outcomes from the same simulation starting conditions or if the simulations share a common predicted outcome. In some cases, a predicted outcome may comprise the development of a quantum computer with practical applications, such as by governments and large corporations. In a further embodiment, a predicted outcome may comprise the development of a quantum computer which can be marked to commercial and consumer markets.

Predicting at step 908, the likelihood that the predicted outcome may occur based on collected data. The prediction may be calculated using one or more simulations similar to the simulation model simulations, but unlike the simulation model simulations, the predictions will utilize and be influenced by the collected data. In some embodiments, the collected data may be used as initial parameters used by one or more simulation models to simulate whether the likelihood of the selected predicted outcome being realized increases. In other embodiments, the predictions may be made based upon analysis by a large language model, natural language processing system, or other artificial intelligence model or simulation. In some cases, determining that the likelihood of increased Houthi rebel violence in the Red Sea is 78%. In some embodiments, the likelihood of realization may be a qualitative value, such as high, medium, or low, which may be based on whether a quantitative value is above a threshold value. In some cases, if the threshold value for high likelihood is 75%, then the 78% likelihood of increased Houthi rebel violence in the Red Sea would indicate a high likelihood of realization. Likewise, if the likelihood was predicted at 73%, the likelihood may be considered medium.

Predicting at step 910, the impact the predicted outcome may have if it were to be realized. The prediction may be calculated using one or more simulations similar to the simulation model simulations, but unlike the simulation model simulations, the predictions will utilize and be influenced by the collected data. In some embodiments, the collected data may be used as initial parameters used by one or more simulation models to simulate the impact of the predicted outcome. The impact may be calculated based on one or more metrics such as casualties, fatalities, cost of damages, time until recovery, etc. Predicted impacts may be qualitative or quantitative. Qualitative impact may comprise estimated numbers, such as 5 fatalities, 12 casualties, and $200 million in economic losses in the month of April 2024, in the Red Sea resulting from Houthi Rebel violence. In some embodiments, the impact may be represented as high, medium, or low, which may be based on threshold values. In some embodiments, the threshold values may be selected based on the relative severity of the simulation. For example, 5 fatalities and 12 casualties may be high for attacks on ships that have relatively small crews but may be relatively low if instead considering an incident involving a commercial passenger airliner.

Determining at step 912, a risk score based on the likelihood of realization and the impact of realization of the predicted outcome. In some embodiments, the risk score may be calculated based on multiplying a probability representing the likelihood of realization by an impact metric. In some embodiments, the risk score may utilize an algorithm that may account for multiple metrics, such as a weighted average where casualties are weighted at 2, fatalities are weighted at 5, and monetary losses are divided by 10 million. The weighted average may then be multiplied by the likelihood of realization to obtain a risk score. In some embodiments, the risk score may comprise discrete components, such as a risk of casualties, fatalities, monetary losses, etc.

For example, 5 fatalities, 12 casualties, losses of $200 million, and a likelihood of 78%, would result in a risk score of 53.82. This risk score could be used to compare the relative risk of different types of events based on the severity of the impact and the risk of the outcome occurring. In some embodiments, the risk score may comprise discrete metrics, such as the number of fatalities and casualties, the amount of monetary damages or losses, and the likelihood of the event occurring. In some embodiments, a risk assessment may comprise a subjective risk assessment which may not have quantitative impacts, or which may require more extensive simulations or broader measures of impact. For example, the results of a political election may not have immediately quantifiable impacts in terms of impacts to government spending, economic impact, etc. Further simulations may be required, which may represent differing outcomes which may follow the predicted election results. For example, the election results may increase or decrease the likelihood of war.

Saving at step 914, a risk score to the simulation model database 112. The simulation model database 112 stores data comprising predicted outcomes, a risk score, and a description of the predicted outcome or story ending and potential consequences. In some embodiments, the risk score may comprise an aggregate value or a plurality of discrete values for different elements of risk. The risk score may comprise a quantitative number, or a qualitative value such as high, medium, or low. Determining at decision block 916, whether there are more predicted outcomes to be assessed for risk. If there are additional predicted outcomes, return to step 906 and select one or more predicted outcomes to be assessed for risk. In some cases, another predicted outcome to be assessed is “wildfires from drought.” Sending at step 918, a risk assessment of one or more predicted outcomes to the control module 120.

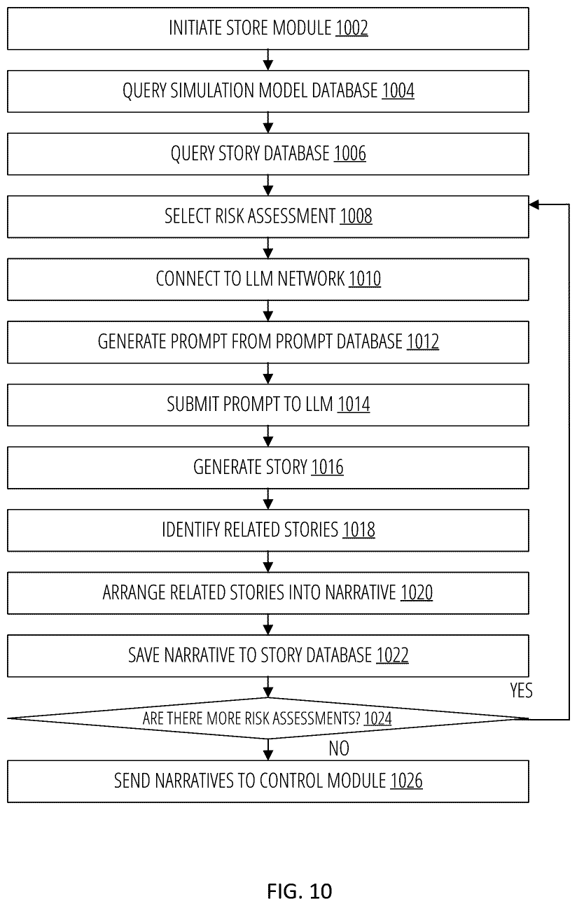

FIG. 10 illustrates a story module.

FIG. 10 illustrates the story module 130. The process begins with initiating at step 1002, the story module 130, by the control module 120. Querying at step 1004, the simulation model database 112. The simulation model database 112 stores simulation models, which in some cases are pure simulations unaffected by external data and the results of simulations that may include one or more predicted outcomes, data collected by the data collection module 126, and risk assessments determined by the risk assessment module 128. Querying at step 1006, the story database 116 for existing stories and any associated data such as predicted outcomes, simulation results, risk assessments, collected data, etc., which may be associated with the stories. Stories comprise narratives or text descriptions of hypothetical future events and/or actual past events. Stories may include factual data and/or observations including data collected by the data collection module 126, and fictional information, such as may be provided by the story module 130 and/or a large language model. The stories are created to illustrate the significance of risks identified by the risk assessment module 128.

Selecting at step 1008, a risk assessment from the data retrieved from the simulation model database 112. The risk assessments may be paired with one or more predicted outcomes, such as “Houthi rebel increased violence in the Red Sea,” may be paired with a risk assessment comprising a 78% likelihood of increased violence in the Red Sea and a potential impact of 5 fatalities, 12 casualties, and $200 million in economic losses. Connecting at step 1010, to a large language model network. In some embodiments, the connection may comprise the submission of hypertext transfer protocol (HTTP) requests via an application programming interface (API). A large language model network may comprise an open-source or proprietary large language model. In some embodiments, a large language model network may be hosted by a third-party network 136. Examples of a large language model include OpenAI's ChatGPT, Google's Bard and Gemini, Microsoft's Bing, and Facebook's LLaMA. Large language models may comprise monomodal or multimodal models. A monomodal model receives prompts and returns responses using the same data type, such as text. A multimodal model can receive and/or return responses using different data types such as text, speech, or other audio, images, video, etc. A large language model may also refer to a natural language processing service such as PrimerAI, which may utilize methods other than large language models and generative AI, such as traditional natural language processing methods that convert natural language text, audio, or visual input into data which may be used in computational processing by one or more computing systems.

Generating at step 1012, a prompt from the prompt database 114. The prompt database 114 may store previously generated prompts which may comprise a data component and a request component. The data component is structured to provide context regarding data that is provided with the request, and the request component describes the type of response to be returned by the large language model. In some embodiments, the large language model may be fine-tuned for a specific purpose. Fine-tuning comprises a process of further training a pre-trained generative transformer with task-specific data, including a correct response, also known as a label. In some embodiments, prompts may be generated for different large language models depending on the type of data and/or request being generated. In some embodiments, the prompts in a prompt database 114 may have been generated by a large language model. Some embodiments may include a [data] component of the prompt, which is a placeholder for data, which may be found in a database.

In some embodiments, data may be acquired via one or more sensors, receiving user input, etc. In some cases, a prompt may comprise an information component of “Using data from the collected data: [data] matching the predicted outcome [data],” and a request component of “Provide a summary of events according to the correlated data.” Submitting at step 1014, the generated prompt to the large language model network. In some cases, the prompt may be submitted as an HTTP request via an API. In other embodiments, the large language model may be integrated into an event monitoring system 102, and therefore, a prompt may be submitted directly. A prompt may comprise multiple components, including a data component and a request component. A prompt may additionally comprise a system prompt, which may provide further context for the type of response to be returned. For example, a system prompt may instruct the large language model to provide a text response from the perspective of an insurance risk analyst seeking to describe the potential significance of risk based upon a provided risk assessment. The prompt may be submitted in text or as speech. In some embodiments, the data component may additionally comprise data tables, charts, figures, etc. In some embodiments, a prompt may further include a request component describing the information to be returned by the large language model.

Generating at step 1016, a story by receiving a response from the large language model. The response may be in the form of natural speech or text or may include other modes such as images, data, etc. In some embodiments, the response may be received in a series of iterative prompt and response cycles such that the large language model may generate an additional prompt as part of the response to receive additional information. For example, the story may describe the provided risk assessment, collected data, and predicted outcome events using natural language, which may comprise a hypothetical simulation. The story may include the provided data via direct reference, such as describing a cost of damage, or may use the provided data indirectly, such as to determine a level of damage. For example, if damages were calculated at $100 million dollars involving a bridge, the bridge may have collapsed, whereas damages of $10 million dollars or less may indicate possible structural damage, but the structure may otherwise be intact. In some cases, a first prompt may comprise an information component of “Using data from the collected data: [data] matching the predicted outcome [data],” and a request component of “Provide a summary of events according to the correlated data.” The [data] placeholder may refer to a predicted outcome identified by the simulation model module 124 and data collected by the data collection module 126. The data may be stored in the simulation model database 112 and may additionally be stored in the parameter database 110.

In some embodiments, data may additionally be used from the story database 116 or one or more third-party databases 138. A story may comprise a summary such as “Houthi rebel violence in the Red Sea has increased significantly, with a 78% likelihood of casualties and economic losses which could reach as many as 5 fatalities, 12 casualties, and $200 million in economic losses from loss of ships and cargo and disruptions to shipping lanes in and around the Red Sea.” In another embodiment, a prompt may comprise an information component of “For the predicted outcome [data], use the simulation model results [data] to,” and a request component of “Generate a timeline of notable events.” The resulting story may comprise a chronological account of events in and around the Red Sea, including past events, such as previous attacks by Houthi rebels in the Red Sea, and a description of possible future attacks and impacts on shipping traffic from diversions to avoid the conflict zone, potential losses, etc. In some embodiments, the generated stories may additionally comprise a headline, or single phrase or sentence summarizing the story and/or outcome. The generated story may further include a status or momentum toward an outcome, such as emerging, likely, inevitable, etc.

Identifying at step 1018, stories related to the generated story. Related stories may be determined based on common keywords, tags, themes, etc., and may utilize both the source data and generated story data to determine whether the stories are related. In some embodiments, the identification of related stories may utilize large language models and/or natural language processing systems. Identification may comprise a process of methodically comparing data from the current generated story to data from existing stories. Related stories may match one or more keywords or be matched using machine learning algorithms, which may include large language models, to determine whether the stories comprise related contexts, such as people, location, time, type of events, objects, outcomes, similar structures and momentum, etc. For example, stories describing Houthi rebels may be related, as would stories related to the Red Sea. In some embodiments, stories may be related only if a plurality of keywords or context elements match, such as “Houthi rebels,” “Red Sea,” and “violence.” In some embodiments, novel connections represent emergent risks comprising cascading impacts and novel emerging risk categories, or predefined risks, such as those described in insurance contracts. Narratives and stories which may represent imaginged futures may be linked, such as by system variables. These may include, for example, a similar story about climate change, water and food shortages gaining momentum in different regions, or that climate policy is weakened by global insecurity or vice versa.

Arranging at step 1020, the generated story, and related stories into a narrative format. The generated story is analyzed to determine when in a timeline relevant to the related stories the generated story occurs and insert the generated story into the related stories. The imagined future outcomes may be described in narrative form, a form of model-free exploration that may not rely on detailed evidence. One of the essential differences between existing systems and the event monitoring system 102 is the codifying of expansive, possible, and extreme imagined futures to avoid presentism and inherent status quo and confirmation biases. These narratives form the basis for monitoring catastrophic risk endgames or invention outcomes. For example, war may be an endgame, as may famine or mass migration. These outcomes are imagined, possible, worst- or best-case outcomes over time, though they are not linear. War can lead to famine or energy crises, or famine can lead to war. In some embodiments, the simulation matrix is a live dashboard that may be applied to any complex system characterized by multiple protagonists, high levels of system noise, and high volumes of data and information in media, social media, and academic literature that disguise underlying emerging realities. The dashboard, or simulation matrix, may display momentum, whether positive or negative. In some cases, the momentum direction may be indicated via color, such that red may represent momentum in the negative direction, and green may represent momentum in the positive direction.

The dashboard may contain links to narratives and/or underlying data sources. There may be links between boxes or cells in the simulation matrix which may represent relationships. Likewise, emergence may be indicated, as may severity of the possible outcome. In some embodiments, indications may be present which inform the user of the best-case simulation, and likewise the worst-case simulation. The dashboard may be updated dynamically as new information, simulation results, etc. become available and in response to potential policy decisions, whether hypothetical or actual. In this way, simulated outcomes within the simulation matrix may test possible policy interventions or the impact of breakthrough inventions. The dashboard provides situation awareness, highlighting the emergence of social, political, or economic shocks in anticipation of future events, such that urgent policy actions may be triggered, such as early action to protect vulnerable coastal regions. Saving at step 1022, the narrative to the story database 116. Determining at decision block 1024, if there are more risk assessments for which a story must be generated. If there are more risk assessments, return to step 1008 and select another risk assessment. In some cases, additional risk assessments include the risk of wildfires from drought conditions. Sending at step 1026, the generated narratives to the control module 120.

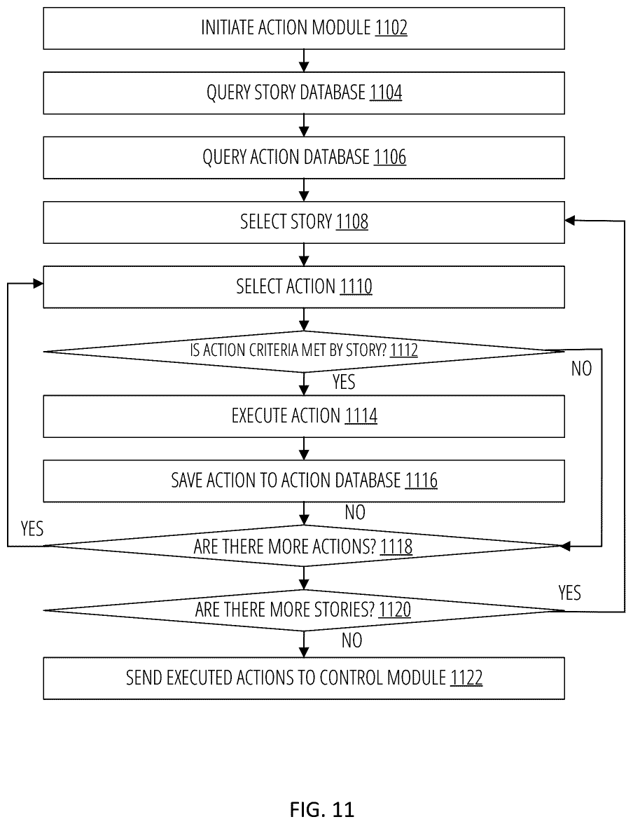

FIG. 11 illustrates an action module.

The process begins with initiating at step 1102, the action module 132 by the control module 120. Querying at step 1104, the story database 116. The story database 116 stores stories and associated data such as predicted outcomes, simulation results, risk assessments, collected data, etc. The stories may comprise narratives comprising a collection of stories. The stories may comprise data in a variety of formats, including text, audio, images, video, data tables, etc. In some embodiments, a single story may include data in multiple formats, such as a text description accompanied by an image and a data table with information that may support the text description. In some embodiments, the story data may be in the form of a dashboard viewable by users of an event monitoring system 102, which may represent the current status or momentum towards an outcome or multiple outcomes. The matrix may be presented as a representational model of interrelated or independent systems and variables, a navigational dashboard, or a specialist development of multi-variant, multi-level morphological space that represents and monitors variables and outcomes over time. The current status may represent a threat status or an intervention status. For example, a threat status may be emerging or imminent, whereas an intervention status may comprise likely, ongoing, inevitable, etc. The status may alternatively indicate an outcome or response, such as escalation, cold war, collaboration, accidental war, etc.

Querying at step 1106, the action database 118. The action database 118 stores actions and the trigger conditions, which indicate when the action should be executed. The actions may comprise a person and method of notification, a digital control, such as adjusting a value in a database or algorithm, issuing a command to a server or device, actuating a servo or other control mechanism, etc. Examples of triggers may include data exceeding a threshold value, type of event or outcome, etc. In some embodiments, actions may have multiple trigger conditions. Similarly, some trigger conditions may be associated with multiple actions. The actions and trigger conditions may be manually defined by a user. In some cases, the trigger condition may comprise the relationship between drought and nuclear power system water supply shortages or threats to hydropower shutdowns. In some cases, the trigger condition may comprise the development of a quantum computer capable of compromising the security of encryption used in financial markets, and the action may include the adoption or implementation of a more advanced encryption method by financial markets and/or governments. In other embodiments, the trigger condition may comprise food or water shortages, and the associated action may comprise rationing or more strict water management measures.

Selecting at step 1108, a story from the data received from the story database 116. In some cases, selecting the story, “Houthi rebel violence in the Red Sea has increased significantly, with a 78% likelihood of casualties and economic losses which could reach as many as 5 fatalities, 12 casualties, and $200 million in economic losses from loss of ships and cargo and disruptions to shipping lanes in and around the Red Sea.” Selecting at step 1110, an action from the data received from the action database 118. The action may additionally comprise the associated trigger condition. In some embodiments, an action may require multiple trigger conditions. In some cases, select the action to increase the insurance rate by 50%. In another embodiment, select the action to revoke an insurance policy. In another embodiment, restrict water usage. Determining at decision block 1112, whether the action criteria have been met by the story. The action criteria may comprise one or more trigger conditions required by the action. In some cases, the action criteria for increasing an insurance rate by 50% is if projected casualties are greater than one. With projected casualties being 12, the action criteria are met by the story. If the action criteria have not been met, determine whether there are more actions. Executing at step 1114, the action if the action criteria are met by the selected story. In some cases, increasing the rate of the insurance policy for a ship navigating through the Red Sea by 50% because the projected casualties are greater than one. In another embodiment, decrease the insurance policy by 25% because the ship diverted from the Red Sea, which was determined to be a high-risk region. In another embodiment, requesting additional firefighting resources because wildfire growth exceeds 1,000 acres per day. In another embodiment, presenting a pre-defined set of military or policy options to policymakers, or generating possible options and hedging strategies.

Examples of actions may include notifications or alerts based on criteria, such as an emerging relationship or link between predicted outcomes or increasing momentum toward an outcome. In some embodiments, the outcomes may be detected by the user of an event monitoring system 102. Alternatively, the outcomes of interest may be defined based on indirect criteria, such as relating to China, or relating to a military threat or action. In some embodiments, an action may comprise releasing preapproved press releases in response to the detection of disinformation, which simulations have indicated may sway public opinion against a policy, such as public support of providing military aid to Ukraine or Israel. In some embodiments, the action may comprise submitting a report to a database administrator that their database is hosting disinformation and may further provide evidence supporting the assertion that the information is false. In some embodiments, pre-planned actions, contingency plans, or rapid responses to novel events, may be executed. These are dynamic hedging and options designed to respond to systemic cascading events and both explicit and latent risk. Hedging and options strategies may be stress-tested, represented in the form on one or more possible simulation pathways, or a definition of pathways or policies that will create say the conditions for peace and conflict resolution.

Saving at step 1116, the executed action to the action database 118 associated with the selected action. Determining at decision block 1118, whether there are more actions to be evaluated. If there are more actions, return to step 1110 and select another action. In some cases, there are additional actions to be considered, including revoking an insurance policy. Determining at decision block 1120, whether there are more stories to be evaluated for indicated actions. If there are more stories, return to step 1108 and select another story. In some cases, there are more stories, including drought leading to wildfires in the western US. Sending at step 1122, the executed actions to the control module 120.

The functions performed in the processes and methods may be implemented in differing order. Furthermore, the outlined steps and operations are only provided as examples, and some of the steps and operations may be optional, combined into fewer steps and operations, or expanded into additional steps and operations without detracting from the essence of the disclosed embodiments.

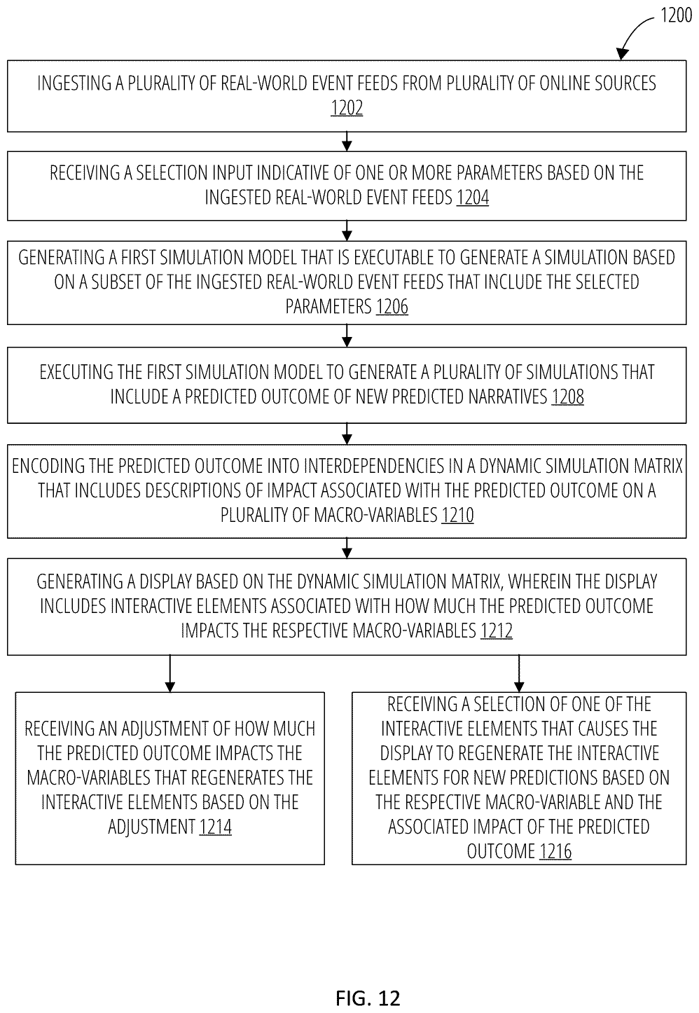

FIG. 12 illustrates an example method for generating a dynamic simulation matrix. Although the example method 1200 depicts a particular sequence of operations, the sequence may be altered without departing from the scope of the present disclosure. For example, some of the operations depicted may be performed in parallel or in a different sequence that does not materially affect the function of the method 1200. In other examples, different components of an example device or system that implements the method 1200 may perform functions at substantially the same time or in a specific sequence.

According to some examples, the method includes ingesting a plurality of historical narrative data feeds from plurality of online sources at step 1202. In some cases, the event monitoring system 102 or the data collection module 126 may ingest the historical narrative data feeds. In some cases, the historical narrative data feeds include real-time updates. In some cases, based on the ingested historical narrative data feeds, an initial targeted simulation is determined. In some cases, an initial simulation matrix may be generated for display. The initial simulation matrix may include descriptions of impact on a plurality of macro-variables in the initial targeted simulation. In some cases, the initial target simulation is determined based on a selected topic by a user.

According to some examples, the method includes receiving a selection input indicative of one or more parameters based on the ingested real-world event feeds at step 1204. In some cases, the event monitoring system 102 or the parameter identification module 122 may receive the selection input indicative of one or more parameters. According to some examples, the method includes generating a first simulation model that is executable to generate a simulation based on a subset of the ingested real-world event feeds that include the selected parameters at step 1206. In some cases, the event monitoring system 102 or the simulation model module 124 may generate the first simulation model.

According to some examples, the method includes executing the first simulation model to generate a plurality of simulations in an isolated execution that include one or more predicted outcomes of new predicted narratives at step 1208. In some cases, the event monitoring system 102 or the simulation model module 124 may generate the first simulation model. In some cases, the method includes executing the first simulation model to generate a plurality of simulations in an isolated execution that include one or more predicted outcomes of new predicted narratives at step 1208. The predicted outcomes are anomalous events or simulations that arise from application of machine learning algorithms to the historical data narrative data feeds that generated the first simulation model but is not directly derived from those same events. As such, the predicted outcome refers to a result or consequence that emerges from the simulation model's analysis of historical patterns and trends but is not necessarily grounded in actual historical occurrence. The predicted outcome represents an unexpected or unanticipated event that is informed by the machine learning model's training on historical data but does not directly correspond to any specific real-world event.

According to some examples, the method includes encoding the one or more predicted outcomes into interdependencies in a dynamic simulation matrix that includes descriptions of impact on a plurality of macro-variables at step 1210. In some cases, the event monitoring system 102 or the simulation model module 124 may encode the one or more predicted outcomes. The encoding process may involve integrating the predicted outcome with the interdependencies between macro-variables. In some cases, a directed acyclic graph (DAG) forms the interdependencies between the plurality of macro-variables in a closed-loop diagram may be generated. The dynamic simulation matrix may be encoded based on the DAG.

In some cases, the encoded dynamic simulation matrix may capture how the one or more predicted outcomes impacts the various macro-variables. For example, the predicted outcome is incorporated into the dynamic simulation matrix by assigning a specific weight or influence value that determines a level of impact of the predicted outcome on each affected macro-variable in the framework of a particular context. In some cases, different interactive elements may be associated with the same macro-variable, but directed at a specific level of effect. For example, a macro-variable may have multiple interactive elements corresponding to different levels of impact: one element representing a low-level effect, another representing a moderate effect, and yet another representing a high-level effect.

In some cases, a selection of one of the macro-variables associated with one of the predicted outcomes may be received. A search query based on the selected macro-variable and the associated predicted outcome may be generated. In some cases, generating the search query includes generating a prompt for a large language model that is a pre-trained generative transformer with task-specific data. In some cases, the search query includes an algorithmic composition of search terms including the predicted outcome and contextual information related to the selected macro-variable. In some cases, the search query is submitted as a database query in the form of structured query language (SQL).

In some cases, the generated search query and receiving query results may be submitted and, based on query results, one or more stories may be generated in a narrative format using a large-language model. The stories may be summarized as different types of interventions, and the different types of interventions may be encoded in interactive elements in the dynamic simulation matrix. The encoded different types of interventions may be updated based on real-time data from the historical narrative data feeds.

In some cases, key indicators are monitored based on a measurement of emotional response within the stories based on a machine-learning algorithm. The encoding the different types of interventions may be based on the monitoring of the key indicators. In some cases, based on at least one of the monitored key indicators or the encoded different types of interventions, a DAG that forms interdependencies between the plurality of macro-variables in a closed-loop diagram may be generated.

According to some examples, the method includes generating a display based on the dynamic simulation matrix, wherein the display includes one or more interactive elements associated with respective macro-variables and varying effects of the predicted outcome at step 1212. In some cases, the event monitoring system 102 or the story module 130 may generate the display based on the dynamic simulation matrix.

According to some examples, the method includes receiving an adjustment of impact of how the predicted outcome effects the macro-variables that regenerates the interactive elements based on the adjustment in step 1214. In some cases, rather than including the various effects as interactive elements, there may be an adjustment element that receives an adjustment of how the predicted outcome would effect the various macro-variables.

In addition to or alternatively, the method includes receiving a selection of one of the interactive elements that causes the display to regenerate the interactive elements based on the selected macro-variable and the associated effect of the predicted outcome in step 1216. For example, the selected interactive element associated with the respective macro-variable may be “the US economy” and is associated with discussion of how the predicted outcome effects the US economy, such as that the predicted outcome is predicted to results in a negative impact on the stock market. Selecting the respective interactive element would regenerate the interactive elements to recalibrate all the various macro-variables based on an assumption that the predicted outcome resulted in a negative impact on the stock market.

In some cases, the first simulation model may define a machine-learning model and receive additional real-time feed data. Based on the additional real-time feed data, the machine-learning model may determine that a breakthrough event has occurred that signals a shift above a threshold limit of likelihood of realization associated with the predicted outcome compared to other predicted outcomes that are characterized by competing or contested outcomes over time.

In some case, the machine-learning model may identify the breakthrough event using one or more of the following methods: a anomaly detection, an algorithm that uses statistical methods to detect anomalies in real-time real-world event feeds that indicate potential breakthroughs; pattern mining, which uses an algorithm applies pattern mining techniques to identify patterns in data that suggest emerging narratives or unexpected outcomes, a graph-based approach, an algorithm uses graph theory and network analysis to model relationships between entities, concepts, and events in the data, highlighting potential breakthroughs as nodes or edges with unusual properties; a clustering and segmentation approach, an algorithm that groups similar data points into clusters, then applies segmentation techniques to identify sub-clusters that suggest emerging trends or breakthroughs; text mining and sentiment analysis, using natural language processing (NLP) and sentiment analysis to extract insights from text-based real-world event feeds, highlighting potential breakthroughs as words or phrases with unusual sentiment patterns; deep learning, by using Convolutional Neural Networks (CNNs), Recurrent Neural Networks (RNNs), or other deep learning architectures to analyze and model complex relationships in data, reinforcement learning, by utilizing reinforcement learning algorithms to learn from interactions with the environment and adaptively identify potential breakthroughs; or generative models (e.g., Generative Adversarial Networks) that generate new data that reflects emerging patterns or trends.

In some cases, a threshold value for one or more predicted outcomes may be determined. In some cases, a signal value of real-time data may be compared to the threshold value to determine if a trigger condition has been met. In response to the trigger condition being met, a signal may be transmitted to an action module to perform a predetermined action.

The threshold value for predicted outcomes associated with simulation model module 124 is determined through a machine learning-based process, wherein a neural network (NN) model is trained on a dataset of real-world event feeds to identify patterns indicative of anomalies or potential security threats. The NN model outputs a weighted score (WS) that reflects the likelihood of a particular real-world event feed being indicative of an anomaly, which is then normalized to produce a probability value (PV) between 0 and 1. The PV value serves as the threshold value for predicted outcomes, such that any received real-world event feed with a PV value greater than or equal to a predetermined confidence level (e.g., 0.7) is considered indicative of an anomaly and triggers the action module 132 to perform a predetermined action.

In this example, the threshold value may be determined through a machine learning-based process using a neural network model. The output of the NN model is a weighted score (WS) that reflects the likelihood of a particular real-world event feed being indicative of an anomaly. This WS value is then normalized to produce a probability value (PV) between 0 and 1, which serves as the threshold value for predicted outcomes. The PV value can be adjusted based on various factors, such as the confidence level required for triggering the action module. In this example, a PV value of 0.7 or greater is used to indicate that an anomaly has been detected and trigger the action module to perform a predetermined action.

In some cases, an alert may be generated in a dynamic dashboard displaying the dynamic simulation matrix based on the breakthrough. In some cases, a selection associated with the alert may be received and a second simulation model may generate a plurality of new simulations in a different an isolated execution based on the breakthrough. The generated new simulations may include one or more new predicted outcomes of new emerging narratives. In some cases, the one or more new predicted outcomes may be encoded in a new dynamic simulation matrix that includes descriptions of impact of a new particular context on a plurality of new macro-variables. In some cases, the new dynamic simulation matrix may be presented. The new dynamic simulation matrix may includes one or more new interactive elements associated with each of the new macro-variables.

In some cases, a large-scale simulation library of predicted outcomes of new emerging narratives that emerge over time may be formed. Based on the large-scare simulation library, in some cases, simulation models may be linked together to form a live updated knowledge graph that shows existing, emerging, or new sets of relationships. In some cases, a simulated future relationship may be defined based on the live updated knowledge graph. A new simulation model may be generated based on the simulated future relationship that represents a combination of events or developments.

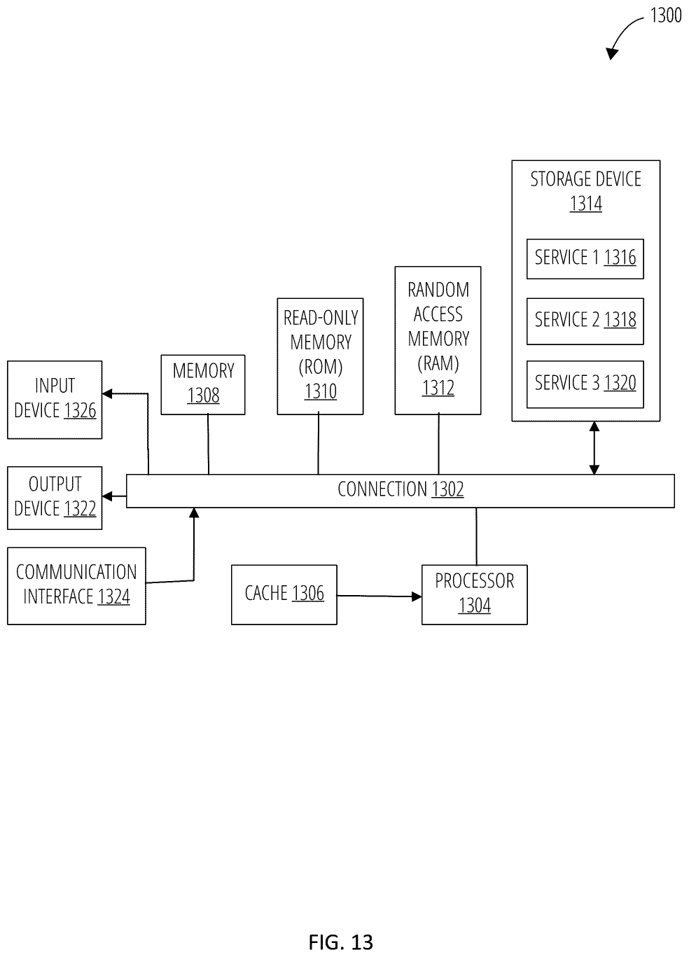

FIG. 13 illustrates a block diagram of an exemplary computing system. The example of computer system 1300 can be for example any computing device making up the risk management system 100, or any component thereof in which the components of the system are in communication with each other using connection 1302. Connection 1302 can be a physical connection via a bus, or a direct connection into processor 1304, such as in a chipset architecture. Connection 1302 can also be a virtual connection, networked connection, or logical connection.

In some embodiments, computer system 1300 is a distributed system in which the functions described in this disclosure can be distributed within a datacenter, multiple data centers, a peer network, etc. In some embodiments, one or more of the described system components represents many such components each performing some or all of the function for which the component is described. In some embodiments, the components can be physical or virtual devices.

Example computing system 1300 includes at least one processing unit (CPU or processor) 1304 and connection 1302 that couples various system components including system memory 1308, such as read-only memory (ROM) 1310 and random access memory (RAM) 1312 to processor 1304. Computing system 1300 can include a cache of high-speed memory 1308 connected directly with, in close proximity to, or integrated as part of processor 1304.

Processor 1304 can include any general purpose processor and a hardware service or software service, such as services 1316, 1318, and 1320 stored in storage devices 1314, configured to control processor 1304 as well as a special-purpose processor where software instructions are incorporated into the actual processor design. Processor 1304 may essentially be a completely self-contained computing system, containing multiple cores or processors, a bus, memory controller, cache, etc. A multi-core processor may be symmetric or asymmetric.

To enable user interaction, computer system 1300 includes an input device 1326, which can represent any number of input mechanisms, such as a microphone for speech, a touch-sensitive screen for gesture or graphical input, keyboard, mouse, motion input, speech, etc. Computing system 1300 can also include output device 1322, which can be one or more of a number of output mechanisms known to those of skill in the art. In some instances, multimodal systems can enable a user to provide multiple types of input/output to communicate with computer system 1300. Computer system 1300 can include communication interface 1324, which can generally govern and manage the user input and system output. There is no restriction on operating on any particular hardware arrangement, and therefore the basic features here may easily be substituted for improved hardware or firmware arrangements as they are developed.

Storage device 1314 can be a non-volatile memory device and can be a hard disk or other types of computer readable media which can store data that are accessible by a computer, such as magnetic cassettes, flash memory cards, solid state memory devices, digital versatile disks, cartridges, random access memories (RAMs), read-only memory (ROM), and/or some combination of these devices.

The storage device 1314 can include software services, servers, services, etc., that when the code that defines such software is executed by the processor 1304, it causes the system to perform a function. In some embodiments, a hardware service that performs a particular function can include the software component stored in a computer-readable medium in connection with the hardware components, such as processor 1304, connection 1302, output device 1322, etc., to carry out the function.

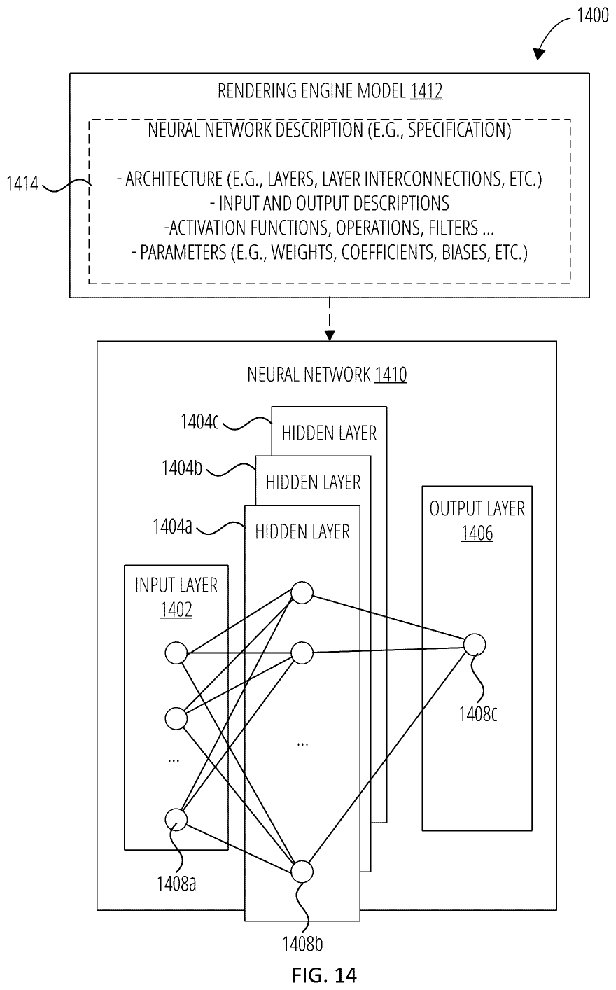

FIG. 14 illustrates an example neural network architecture.

Architecture 1400 includes a neural network 1410 defined by an example neural network description 1414 in node 1408c (neural controller). The neural network 1410 can represent a neural network implementation of a rendering engine for rendering media data. The neural network description 1414 can include a full specification of the neural network 1410, including the neural network architecture 1400. For example, the neural network description 1414 can include a description or specification of the architecture 1400 of the neural network 1410 (e.g., the layers, layer interconnections, number of nodes in each layer, etc.); an input and output description which indicates how the input and output are formed or processed; an indication of the activation functions in the neural network, the operations or filters in the neural network, etc.; neural network parameters such as weights, biases, etc.; and so forth.

The neural network 1410 reflects the architecture 1400 defined in the input layer 1402. In this example, the neural network 1410 includes an input layer 1402, which includes input data, such as stored current features and stored historical features including at least one of device health, user behavior, network activity, previous scores, login attempts, or system updates that provide context about past events. In one illustrative example, the input layer 1402 can include data representing a portion of the input media data such as a patch of data or pixels in an image corresponding to the input media data. The neural network 1410 includes hidden layers 1404a through 1404 N (collectively “1404” hereinafter). The hidden layers 1404 can include n number of hidden layers, where n is an integer greater than or equal to one. The number of hidden layers can include as many layers as needed for a desired processing outcome and/or rendering intent.

The neural network 1410 further includes an output layer 1406 that provides an output (e.g., rendering output) resulting from the processing performed by the hidden layers 1404. In one illustrative example, the output layer 1406 can provide machine-learning factors including one or more clusters representing devices and users with similar trust levels, one or more alert flags indicating potential trustworthiness issues, one or more predicted trust scores, or one or more predicted labels indicating trustworthiness of a device or user. The neural network 1410 in this example is a multi-layer neural network of interconnected nodes. Each node can represent a piece of information. Information associated with the nodes is shared among the different layers and each layer retains information as information is processed. In some cases, the neural network 1410 can include a feed-forward neural network, in which case there are no feedback connections where outputs of the neural network are fed back into itself. In other cases, the neural network 1410 can include a recurrent neural network, which can have loops that allow information to be carried across nodes while reading in input. Information can be exchanged between nodes through node-to-node interconnections between the various layers.

Nodes of the input layer 1402 can activate a set of nodes in the first hidden layer 1404a. For example, as shown, each of the input nodes of the input layer 1402 is connected to each of the nodes of the first hidden layer 1404a. The nodes of the hidden layers hidden layer 1404a can transform the information of each input node by applying activation functions to the information. The information derived from the transformation can then be passed to and can activate the nodes of the next hidden layer (e.g., 1404b), which can perform their own designated functions. Example functions include convolutional, up-sampling, data transformation, pooling, and/or any other suitable functions. The output of the hidden layer (e.g., 1404b) can then activate nodes of the next hidden layer (e.g., 1404N), and so on. The output of the last hidden layer can activate one or more nodes of the output layer 1406, at which point an output is provided. In some cases, while nodes (e.g., nodes 1408a, 1408b, 1408c) in the neural network 1410 are shown as having multiple output lines, a node has a single output and all lines shown as being output from a node represent the same output value. In some cases, each node or interconnection between nodes can have a weight that is a set of parameters derived from training the neural network 1410.

For example, an interconnection between nodes can represent a piece of information learned about the interconnected nodes. The interconnection can have a numeric weight that can be tuned (e.g., based on a training dataset), allowing the neural network 1410 to be adaptive to inputs and able to learn as more data is processed. The neural network 1410 can be pre-trained to process the features from the data in the input layer 1402 using the different hidden layers 1404 in order to provide the output through the output layer 1406. In an example in which the neural network 1410 is used to identify the machine-learning factors, the neural network 1410 can be trained using training data that includes generated machine-learning factors, the stored current features, and the stored historical features including at least one of device health, user behavior, network activity, previous scores, login attempts, or system updates that provide context about past events. For instance, training images can be input into the neural network 1410, which can be processed by the neural network 1410 to generate outputs which can be used to tune one or more aspects of the neural network 1410, such as weights, biases, etc. In some cases, the neural network 1410 can adjust weights of nodes using a training process called backpropagation. Backpropagation can include a forward pass, a loss function, a backward pass, and a weight update. The forward pass, loss function, backward pass, and parameter update is performed for one training iteration.

The process can be repeated for a certain number of iterations for each set of training media data until the weights of the layers are accurately tuned. For a first training iteration for the neural network 1410, the output can include values that do not give preference to any particular class due to the weights being randomly selected at initialization. With the initial weights, the neural network 1410 is unable to determine low level features and thus cannot make an accurate determination of what the classification of the object might be. A loss function can be used to analyze errors in the output. Any suitable loss function definition can be used. The loss (or error) can be high for the first training dataset (e.g., images) since the actual values will be different than the predicted output.

The goal of training is to minimize the amount of loss so that the predicted output comports with a target or ideal output. The neural network 1410 can perform a backward pass by determining which inputs (weights) most contributed to the loss of the neural network 1410, and can adjust the weights so that the loss decreases and is eventually minimized. A derivative of the loss with respect to the weights can be computed to determine the weights that contributed most to the loss of the neural network 1410. After the derivative is computed, a weight update can be performed by updating the weights of the filters. For example, the weights can be updated so that they change in the opposite direction of the gradient. A learning rate can be set to any suitable value, with a high learning rate including larger weight updates and a lower value indicating smaller weight updates.

The neural network 1410 can include any suitable neural or deep learning network. One example includes a convolutional neural network (CNN), which includes an input layer and an output layer, with multiple hidden layers between the input and out layers. The hidden layers of a CNN include a series of convolutional, nonlinear, pooling (for downsampling), and fully connected layers. In other examples, the neural network 1410 can represent any other neural or deep learning network, such as an autoencoder, a deep belief nets (DBNs), a recurrent neural networks (RNNs), etc.

For clarity of explanation, in some instances the present technology may be presented as including individual functional blocks including functional blocks comprising devices, device components, steps or routines in a method embodied in software, or combinations of hardware and software.

Any of the steps, operations, functions, or processes described herein may be performed or implemented by a combination of hardware and software services or services, alone or in combination with other devices. In some embodiments, a service can be software that resides in memory of a client device and/or one or more servers of a content management system and perform one or more functions when a processor executes the software associated with the service. In some embodiments, a service is a program, or a collection of programs that carry out a specific function. In some embodiments, a service can be considered a server. The memory can be a non-transitory computer-readable medium.

In some embodiments the computer-readable storage devices, mediums, and memories can include a cable or wireless signal containing a bit stream and the like. However, when mentioned, non-transitory computer-readable storage media expressly exclude media such as energy, carrier signals, electromagnetic waves, and signals per se.

Methods according to the above-described examples can be implemented using computer-executable instructions that are stored or otherwise available from computer readable media. Such instructions can comprise, for example, instructions and data which cause or otherwise configure a general purpose computer, special purpose computer, or special purpose processing device to perform a certain function or group of functions. Portions of computer resources used can be accessible over a network. The computer executable instructions may be, for example, binaries, intermediate format instructions such as assembly language, firmware, or source code. Examples of computer-readable media that may be used to store instructions, information used, and/or information created during methods according to described examples include magnetic or optical disks, solid state memory devices, flash memory, USB devices provided with non-volatile memory, networked storage devices, and so on.

Devices implementing methods according to these disclosures can comprise hardware, firmware and/or software, and can take any of a variety of form factors. Typical examples of such form factors include servers, laptops, smart phones, small form factor personal computers, personal digital assistants, and so on. Functionality described herein also can be embodied in peripherals or add-in cards. Such functionality can also be implemented on a circuit board among different chips or different processes executing in a single device, by way of further example.

The instructions, media for conveying such instructions, computing resources for executing them, and other structures for supporting such computing resources are means for providing the functions described in these disclosures.

Although a variety of examples and other information was used to explain aspects within the scope of the appended claims, no limitation of the claims should be implied based on particular features or arrangements in such examples, as one of ordinary skill would be able to use these examples to derive a wide variety of implementations. Further and although some subject matter may have been described in language specific to examples of structural features and/or method steps, it is to be understood that the subject matter defined in the appended claims is not necessarily limited to these described features or acts. For example, such functionality can be distributed differently or performed in components other than those identified herein. Rather, the described features and steps are disclosed as examples of components of systems and methods within the scope of the appended claims.

What is claimed is:

1. A computer-implemented method comprising:
ingesting a plurality of real-world event feeds from plurality of human and online sources;
receiving a selection input indicative of one or more parameters based on the ingested real-world event feeds;
generating a first simulation model that is executable to generate a simulation based on a subset of the ingested real-world event feeds that include the selected parameters;
executing the first simulation model to generate a plurality of simulations that include a predicted outcome of new predicted narratives;
encoding the predicted outcome into interdependencies in a dynamic simulation matrix that includes descriptions of impact associated with the predicted outcome on a plurality of macro-variables;
generating a display based on the dynamic simulation matrix, wherein the display includes interactive elements associated with how much the predicted outcome impacts the respective macro-variables; and
receiving a selection of one of the interactive elements that causes the display to regenerate the interactive elements for new predictions based on the respective macro-variable and the associated impact of the predicted outcome.

2. The computer-implemented method of claim 1, further comprising:
receiving an adjustment of how much the predicted outcome impacts the macro-variables that regenerates the interactive elements based on the adjustment.

3. The computer-implemented method of claim 1, further comprising:
defining, by the first simulation model, a machine-learning model;
receiving, by the machine-learning model, additional real-time feed data; and
based on the additional real-time feed data, determining, by the machine-learning model, that a breakthrough event has occurred that signals a shift above a threshold limit of likelihood of realization associated with the predicted outcome compared to other predicted outcomes that are characterized by competing or contested outcomes over time.

4. The computer-implemented method of claim 3, further comprising:
encoding the breakthrough event in the dynamic simulation matrix, where the breakthrough event interacts with one or more of the macro-variables; and
generating an updated dynamic simulation matrix that includes one or more new interactive elements based on the encoded breakthrough event.

5. The computer-implemented method of claim 3, further comprising:
generating an alert in a dynamic dashboard displaying the dynamic simulation matrix based on the breakthrough event;
receiving a selection associated with the alert; and
generating, by a second simulation model, a plurality of new simulations based on the breakthrough event, wherein the generated new simulations include one or more new predicted outcomes of new emerging narratives.

6. The computer-implemented method of claim 3, further comprising:
determining a threshold value for one or more predicted outcomes;
comparing a signal value of real-time data to the threshold value to determine if a trigger condition has been met; and
in response to the trigger condition being met, transmitting a signal to an action module to perform a predetermined action.

7. The computer-implemented method of claim 1, further comprising:
receiving a selection of one of the macro-variables associated with one of the predicted outcomes;
generating a search query based on the selected macro-variable and the associated predicted outcome;
submitting the generated search query and receiving query results;
based on query results, generating one or more stories in a narrative format using a large-language model;
summarizing the stories as different types of interventions; and
encoding the different types of interventions in interactive elements in the dynamic simulation matrix.

8. The computer-implemented method of claim 7, wherein the encoded different types of interventions are updated based on real-time data from the real-world event feeds.

9. The computer-implemented method of claim 7, wherein generating the search query includes generating a prompt for a large language model that is a pre-trained generative transformer with task-specific data.

10. The computer-implemented method of claim 9, wherein the search query includes an algorithmic composition of search terms including the predicted outcome and contextual information related to the selected macro-variable.

11. The computer-implemented method of claim 10, wherein the search query is submitted as a database query in a form of structured query language (SQL).

12. The computer-implemented method of claim 7, further comprising:
monitoring key indicators based on a measurement of emotional response within the stories based on a machine-learning algorithm, wherein the encoding the different types of interventions is based on the monitoring.

13. The computer-implemented method of claim 12, further comprising:
based on at least one of the monitored key indicators or the encoded different types of interventions, generating a directed acyclic graph (DAG) that forms interdependencies between the plurality of macro-variables in a closed-loop diagram.

14. The computer-implemented method of claim 1, further comprising:
generating a directed acyclic graph (DAG) that forms the interdependencies between the plurality of macro-variables in a closed-loop diagram, wherein the dynamic simulation matrix is encoded based on the DAG.

15. The computer-implemented method of claim 1, further comprising:
based on the ingested real-world event feeds, determining an initial targeted simulation; and
generating an initial simulation matrix for display, wherein the initial simulation matrix includes descriptions of impact on a plurality of macro-variables in the initial targeted simulation.

16. The computer-implemented method of claim 15, wherein the initial target simulation is determined based on a selected topic by a user.

17. The computer-implemented method of claim 1, further comprising:
forming a large-scale simulation library of predicted outcomes of new emerging narratives that emerge over time including the one or more predicted outcomes of new emerging narratives.

18. The computer-implemented method of claim 17, further comprising:
based on the large-scale simulation library, linking simulation models together to form a live updated knowledge graph that shows existing, emerging, or new sets of relationships;
defining a simulated future relationship based on the live updated knowledge graph; and
generating a new simulation model based on the simulated future relationship that represents a combination of events or developments.

19. A system comprising:
one or more processors; and
a memory storing instructions that, when executed by the one or more processors, configure the system to:
ingest a plurality of real-world event feeds from plurality of online sources;
receive a selection input indicative of one or more parameters based on the ingested real-world event feeds;
generate a first simulation model that is executable to generate a simulation based on a subset of the ingested real-world event feeds that include the selected parameters;
execute the first simulation model to generate a plurality of simulations that include a predicted outcome of new predicted narratives;
encode the predicted outcome into interdependencies in a dynamic simulation matrix that includes descriptions of impact associated with the predicted outcome on a plurality of macro-variables;
generate a display based on the dynamic simulation matrix, wherein the display includes interactive elements associated with how much the predicted outcome impacts the respective macro-variables; and
receive a selection of one of the interactive elements that causes the display to regenerate the interactive elements for new predictions based on the respective macro-variable and the associated impact of the predicted outcome.

20. A non-transitory computer-readable storage medium, the computer-readable storage medium including instructions that when executed by a computer, cause the computer to:
ingest a plurality of real-world event feeds from plurality of online sources;
receive a selection input indicative of one or more parameters based on the ingested real-world event feeds;
generate a first simulation model that is executable to generate a simulation based on a subset of the ingested real-world event feeds that include the selected parameters;
execute the first simulation model to generate a plurality of simulations that include a predicted outcome of new predicted narratives;
encode the predicted outcome into interdependencies in a dynamic simulation matrix that includes descriptions of impact associated with the predicted outcome on a plurality of macro-variables;
generate a display based on the dynamic simulation matrix, wherein the display includes interactive elements associated with how much the predicted outcome impacts the respective macro-variables; and
receive a selection of one of the interactive elements that causes the display to regenerate the interactive elements for new predictions based on the respective macro-variable and the associated impact of the predicted outcome.
